(19) United States
(12) Patent Application Publication
(10) Pub. No.: US 2009/0039777 A1
(43) Pub. Date: Feb. 12, 2009

(54) ORGANIC ELECTROLUMINESCENT DEVICE AND ELECTRONIC APPARATUS

(75) Inventor: Toshihiro ODA, Fujimi-machi (JP)

Correspondence Address: OLIFF & BERRIDGE, PLC, P.O. BOX 320850, ALEXANDRIA, VA, 22320-4850, US

(73) Assignee: Seiko Epson Corporation, Tokyo (JP)

(21) Appl. No.: 12/185,499

(22) Filed: Aug. 4, 2008

(30) Foreign Application Priority Data
Aug. 7, 2007 (JP) 2007-205041

(51) Int. Cl. H01L 51/54

(52) U.S. Cl. 313/504

(57) ABSTRACT

An organic electroluminescent device includes a translucent first electrode, a translucent second electrode, a luminescent layer, a reflective layer, and a transflective layer. The luminescent layer is arranged between the first electrode and the second electrode. The reflective layer is arranged on an opposite side with respect to the luminescent layer with the first electrode arranged between the reflective layer and the luminescent layer. The reflective layer reflects light, which comes from the luminescent layer, toward the second electrode. The transflective layer is arranged in the same layer with the second electrode or arranged on an opposite side with respect to the luminescent layer with the second electrode arranged between the transflective layer and the luminescent layer. Where λ denotes a peak wavelength of light that is emitted through the second electrode, θ1 denotes a phase shift (rad) of light having a wavelength λ when the light is reflected on the reflective layer, θ2 is a phase shift (rad) of light having a wavelength λ when the light is reflected on the transflective layer, N is an integer that is equal to or larger than 1, and N0 is an integer that is equal to or larger than 1, an optical length L′ between the reflective layer and the transflective layer falls within a range that is expressed by 0.8×(2π·N+θ1+θ2)×λ/(4π)≦L′≦1.2×(2π·N+θ1+θ2)×λ/(4π), and an optical length L′0 between a position, at which light is most intensively generated in the luminescent layer, and the reflective layer falls within a range that is expressed by 0.8×(2π·N0+θ1)×λ/(4π)≦L′0≦1.2×(2π·N0+θ1)×λ/(4π).

### BACKGROUND

1. Technical Field

The present invention relates to an organic electroluminescent device and an electronic apparatus.

2. Related Art

An organic EL device (organic electroluminescent device), that is, an OLED (organic light emitting diode) device, attracts increasing attention as a light source that can achieve a thin and light-weight display. A full-color display that uses organic EL devices has a lot of advantages, such as (1) excellent color purity and (2) small amount of power consumption.

In the field of organic EL device, it has been known that light having a specific wavelength within light generated in a luminescent layer is intensified through interference or resonance and light having the other wavelength is attenuated, and then the light is emitted. For example, Japanese Patent No. 2,797,883 describes that the peak wavelength of light that will be emitted is adjusted in such a manner that a translucent reflective layer and a reflective electrode are arranged on each side of a luminescent layer, and the optical length between the translucent reflective layer and the reflective electrode (between reflection planes) is appropriately set. That is, the optical length between the reflection planes is set in accordance with the peak wavelength of light that will be emitted, so that the optical length may be set so as to coincide with the phase of light having a specific wavelength inside a resonant structure.

According to the above technology, for any pixels, output colors of R (red), G (green) and B (blue) may be obtained even when the luminescent color of each luminescent layer is the same, that is, for example, white. In addition, when the luminescent color is approximate to the color of light that will be emitted (for example, when R light is emitted from a pixel that has a luminescent layer that generates the light of R color, G light is emitted from a pixel that has a luminescent layer that generates the light of G color, and B light is emitted from a pixel that has a luminescent layer that generates the light of B color), it is possible to increase the color purity of light.

In the technology described in Japanese Patent No. 2,797,883, the optical length between the reflection planes is intended to be optimized; however, the position of a luminescent layer interposed between the reflection planes is not particularly adjusted. That is, Japanese Patent No. 2,797,883 does not describe an optical path from the luminescent layer to the reflective electrode or an optical path from the luminescent layer to the translucent reflective layer.

### SUMMARY

An advantage of some aspects of the invention is that it provides an organic electroluminescent device that is able to increase the color purity of light to be emitted and increase the ratio of emitted light to generated light, and it also provides an electronic apparatus.

An aspect of the invention provides an organic electroluminescent device. The organic electroluminescent device includes a translucent first electrode, a translucent second electrode, a luminescent layer, a reflective layer, and a transflective layer. The luminescent layer is arranged between the first electrode and the second electrode. The reflective layer is arranged on an opposite side with respect to the luminescent layer with the first electrode arranged between the reflective layer and the luminescent layer. The reflective layer reflects light, which comes from the luminescent layer, toward the second electrode. The transflective layer is arranged in the same layer with the second electrode or arranged on an opposite side with respect to the luminescent layer with the second electrode arranged between the transflective layer and the luminescent layer. Where λ denotes a peak wavelength of light that is emitted through the second electrode, θ₁ denotes a phase shift (rad) of light having a wavelength λ when the light is reflected on the reflective layer, θ₂ is a phase shift (rad) of light having a wavelength λ when the light is reflected on the transflective layer, N is an integer that is equal to or larger than 1, and N₀ is an integer that is equal to or larger than 1, an optical length L′ between the reflective layer and the transflective layer falls within a range that is expressed by 0.8×(2π·N+θ₁+θ₂)×λ/(4π)≦L′≦1.2×(2π·N+θ₁+θ₂)×λ/(4π) (In equation (1)), and an optical length L′₀ between a position, at which light is most intensively generated in the luminescent layer, and the reflective layer falls within a range that is expressed by 0.8×(2π·N₀+θ₁)×λ/(4π)≦L′₀≦1.2×(2π·N₀+θ₁)×λ/(4π) (In equation (2))

In this manner, because the optical length L′ between the reflective layer and the transflective layer falls within the range that is expressed by In equation (1), it is possible to enhance the color purity around the wavelength λ within light that is emitted through the second electrode, and, hence, it is possible to increase the ratio of light having the wavelength λ to the light that is generated in the luminescent layer. Furthermore, because the optical length L′0 between the position, at which light is most intensively generated in the luminescent layer, and the reflective layer falls within the range that is expressed by In equation (2), it is possible to enhance the color purity around the wavelength λ within light that is emitted through the second electrode, and, hence, it is possible to increase the ratio of light having the wavelength λ to the light that is generated in the luminescent layer.

Another aspect of the invention provides an organic electroluminescent device. The organic electroluminescent device includes a light emitting device of which the color of emitted light is red, a light emitting device of which the color of emitted light is green, and a light emitting device of which the color of emitted light is blue. Each of the light emitting devices includes a translucent first electrode, a translucent second electrode, a luminescent layer, a reflective layer, and a transflective layer. The luminescent layer is arranged between the first electrode and the second electrode. The reflective layer is arranged on an opposite side with respect to the luminescent layer with the first electrode arranged between the reflective layer and the luminescent layer. The reflective layer reflects light, which comes from the luminescent layer, toward the second electrode. The transflective layer is arranged in the same layer with the second electrode or arranged on an opposite side with respect to the luminescent layer with the second electrode arranged between the transflective layer and the luminescent layer. In each of the light emitting devices, where λ denotes a peak wavelength of light that is emitted through the second electrode, θ₁ denotes a phase shift (rad) of light having a wavelength λ when the light is reflected on the reflective layer, θ₂ is a phase shift (rad) of light having a wavelength λ when the light is reflected on the transflective layer, N is an integer that is equal to or larger than 1, and N₀ is an integer that is equal to or larger than 1, an optical length L′ between the reflective layer and the transflective layer falls within a range that is expressed by 0.8×(2π·N+θ₁+θ₂)×λ/(4π)≦L′≦1.2×(2π·N+θ₁+θ₂)×λ/(4π) (In equation (3)), and, in each of the light emitting devices, an optical length L′₀ between a position, at which light is most intensively generated in the luminescent layer, and the reflective layer falls within a range that is expressed by 0.8×(2π·N₀+θ₁)×λ/(4π)≦L′₀≦1.2×(2π·N₀+θ₁)×λ/(4π) (In equation (4)).

In this manner, because, in each of the light emitting devices, the optical length L′ between the reflective layer and the transflective layer falls within the range that is expressed by In equation (3), it is possible to enhance the color purity around the wavelength λ within light that is emitted through the second electrode, and, hence, it is possible to increase the ratio of light having the wavelength λ to the light that is generated in the luminescent layer. Furthermore, because, in each of the light emitting devices, the optical length L′₀ between the position, at which light is most intensively generated in the luminescent layer, and the reflective layer falls within the range that is expressed by In equation (4), it is possible to enhance the color purity around the wavelength λ within light that is emitted through the second electrode, and, hence, it is possible to increase the ratio of light having the wavelength λ to the light that is generated in the luminescent layer.

Further another aspect of the invention provides an organic electroluminescent device. The organic electroluminescent device includes a light emitting device of which the color of emitted light is red, a light emitting device of which the color of emitted light is green, and a light emitting device of which the color of emitted light is blue. Each of the light emitting devices includes a translucent first electrode, a translucent second electrode, a luminescent layer, a reflective layer, and a transflective layer. The luminescent layer is arranged between the first electrode and the second electrode. The reflective layer is arranged on an opposite side with respect to the luminescent layer with the first electrode arranged between the reflective layer and the luminescent layer. The reflective layer reflects light, which comes from the luminescent layer, toward the second electrode. The transflective layer is arranged in the same layer with the second electrode or arranged on an opposite side with respect to the luminescent layer with the second electrode arranged between the transflective layer and the luminescent layer. In each of the light emitting devices, the luminescent layer includes a first luminescent layer of which generated light has a peak intensity at a wavelength corresponding to yellow color, orange color, or red color, and a second luminescent layer of which generated light has a peak intensity at a wavelength corresponding to cyan color or blue color. The first luminescent layer and the second luminescent layer are laminated. In regard to the light emitting device of which the color of emitted light is red, where λ_{R} denotes a peak wavelength of red light that is emitted through the second electrode, θ_{1R} denotes a phase shift (rad) of light having a wavelength λ_{R} when the light is reflected on the reflective layer, θ_{2R} denotes the phase shift (rad) of light having a wavelength λ_{R} when the light is reflected on the transflective layer, N_{R} denotes an integer that is equal to or larger than 1, and N_{0R} denotes an integer that is equal to or larger than 1, an optical length L′_{R} between the reflective layer and the transflective layer falls within a range that is expressed by 0.8×(2π·N_{R}+θ_{1R}+θ_{2R})×λ_{R}/(4π)≦L′_{R}≦1.2×(2π·Nᵣ+θ_{1R}+θ_{2R})×λ_{R}/(4λ) (In equation (5)), and, in regard to the light emitting device of which the color of emitted light is red, an optical length L′_{0R} between a position, at which light is most intensively generated in the first luminescent layer, and the reflective layer falls within a range that is expressed by 0.8×(2π·N_{0R}+θ_{1R})×λ_{R}/(4π)≦L′_{0R}≦1.2×(2π·N_{0R}+θ_{1R})×λ_{R}/(4π) (In equation (6)), wherein, in regard to the light emitting device of which the color of emitted light is green, where λ_{G} denotes a peak wavelength of green light that is emitted through the second electrode, θ_{1G} denotes a phase shift (rad) of light having a wavelength λ_{G} when the light is reflected on the reflective layer, θ_{2G} denotes the phase shift (rad) of light having a wavelength λ_{G} when the light is reflected on the transflective layer, N_{G} denotes an integer that is equal to or larger than 1, and N_{0G} denotes an integer that is equal to or larger than 1, an optical length L′_{G} between the reflective layer and the transflective layer falls within a range that is expressed by 0.8×(2π·N_{G}+θ_{1G}+θ_{2G})×λ_{G}/(4π)≦L′_{G}≦1.2×(2π·N_{G}+θ_{1G}+θ_{2G})×λ_{G}/(4π) (In equation (7)), and, in regard to the light emitting device of which the color of emitted light is green, an optical length L′_{0G} between a position, at which light is most intensively generated in the first or second luminescent layer, and the reflective layer falls within a range that is expressed by 0.8×(2π·N_{0G}+θ_{1G})×λ_{G}/(4π)≦L′_{0G}≦1.2×(2π·N_{0G}+θ_{1G})×λ_{G}/(4π) (In equation (8)), wherein, in regard to the light emitting device of which the color of emitted light is blue, where λ_{B} denotes a peak wavelength of blue light that is emitted through the second electrode, θ_{1B} denotes a phase shift (rad) of light having a wavelength λ_{B} when the light is reflected on the reflective layer, θ_{2B} denotes the phase shift (rad) of light having a wavelength λ_{B} when the light is reflected on the transflective layer, N_{B} denotes an integer that is equal to or larger than 1, and N_{0B} denotes an integer that is equal to or larger than 1, an optical length L′_{B} between the reflective layer and the transflective layer falls within a range that is expressed by 0.8×(2π·N_{B}+θ_{1B}+θ_{2B})×λ_{B}/(4π)≦L′_{B}≦1.2×(2π·N_{B}+θ_{1B}+θ_{2B})×λ_{B}/(4π) (In equation (9)), and, in regard to the light emitting device of which the color of emitted light is blue, an optical length L′_{0B} between a position, at which light is most intensively generated in the second luminescent layer, and the reflective layer falls within a range that is expressed by 0.8×(2π·N_{0B}+θ_{1B})×λ_{B}/(4π)≦L′_{0B}≦1.2×(2π·N_{0B}+θ_{1B})×λ_{B}/(4π) (In equation (10)).

In this aspect as well, in each of the light emitting devices, it is possible to enhance the color purity around the wavelength λ within light that is emitted through the second electrode, and, hence, it is possible to increase the ratio of light having the wavelength λ to the light that is generated in the luminescent layer.

Yet another aspect of the invention provides an organic electroluminescent device. The organic electroluminescent device includes a light emitting device of which the color of emitted light is red, a light emitting device of which the color of emitted light is green, and a light emitting device of which the color of emitted light is blue. Each of the light emitting devices includes a translucent first electrode, a translucent second electrode, a luminescent layer, a reflective layer, and a transflective layer. The luminescent layer is arranged between the first electrode and the second electrode. The reflective layer is arranged on an opposite side with respect to the luminescent layer with the first electrode arranged between the reflective layer and the luminescent layer. The reflective layer reflects light, which comes from the luminescent layer, toward the second electrode. The transflective layer is arranged in the same layer with the second electrode or arranged on an opposite side with respect to the luminescent layer with the second electrode arranged between the transflective layer and the luminescent layer. In each of the light emitting devices, the luminescent layer includes a red luminescent layer of which generated light has a peak intensity at a wavelength corresponding to red color, a green luminescent layer of which generated light has a peak intensity at a wavelength corresponding to green color, and a blue luminescent layer of which generated light has a peak intensity at a wavelength corresponding to blue color. The red luminescent layer, the green luminescent layer, and the blue luminescent layer are laminated. In regard to the light emitting device of which the color of emitted light is red, where λ_{R} denotes a peak wavelength of red light that is emitted through the second electrode, θ_{1R} denotes a phase shift (rad) of light having a wavelength λ_{R} when the light is reflected on the reflective layer, θ_{2R} denotes the phase shift (rad) of light having a wavelength λ_{R} when the light is reflected on the transflective layer, N_{R} denotes an integer that is equal to or larger than 1, and N_{0R} denotes an integer that is equal to or larger than 1, an optical length L′_{R} between the reflective layer and the transflective layer falls within a range that is expressed by 0.8×(2π·N_{R}+θ_{1R}+θ_{2R})×λ_{R}/(4π)≦L′_{R}<1.2×(2π·N_{R}+θ_{1R}+θ_{2R})×λ_{R}/(4π) (In equation (11)), and, in regard to the light emitting device of which the color of emitted light is red, an optical length L′_{0R} between a position, at which light is most intensively generated in the red luminescent layer, and the reflective layer falls within a range that is expressed by 0.8×(2π·N_{0R}+θ_{1R})×λ_{R}/(4π)≦L′_{0R}<1.2×(2π·N_{0R}+θ_{1R})×λ_{R}/(4π) (In equation (12)), wherein, in regard to the light emitting device of which the color of emitted light is green, where λ_{G} denotes a peak wavelength of green light that is emitted through the second electrode, θ_{1G} denotes a phase shift (rad) of light having a wavelength λ_{G} when the light is reflected on the reflective layer, θ_{2G} denotes the phase shift (rad) of light having a wavelength λ_{G} when the light is reflected on the transflective layer, N_{G} denotes an integer that is equal to or larger than 1, and N_{0G} denotes an integer that is equal to or larger than 1, an optical length L′_{G} between the reflective layer and the transflective layer falls within a range that is expressed by 0.8×(2π·N_{G}+θ_{1G}+θ_{2G})×λ_{G}/(4π)≦L′_{G}≦1.2×(2π·N_{G}+θ_{1G}+θ_{2G})×λ_{G}/(4π) (In equation (13)), and, in regard to the light emitting device of which the color of emitted light is green, an optical length L′_{0G} between a position, at which light is most intensively generated in the green luminescent layer, and the reflective layer falls within a range that is expressed by 0.8×(2π·N_{0G}+θ_{1G})×λ_{G}/(4π)≦L′_{0G}≦1.2×(2π·N_{0G}+θ_{1G})×λ_{G}/(4π) (In equation (14)), wherein, in regard to the light emitting device of which the color of emitted light is blue, where λ_{B} denotes a peak wavelength of blue light that is emitted through the second electrode, θ_{1B} denotes a phase shift (rad) of light having a wavelength λ_{B} when the light is reflected on the reflective layer, θ_{2B} denotes the phase shift (rad) of light having a wavelength λ_{B} when the light is reflected on the transflective layer, N_{B} denotes an integer that is equal to or larger than 1, and N_{0B} denotes an integer that is equal to or larger than 1, an optical length L′_{B} between the reflective layer and the transflective layer falls within a range that is expressed by 0.8×(2π·N_{B}+θ_{1B}+θ_{2B})×λ_{B}/(4π)≦L′_{B}≦1.2×(2π·N_{B}+θ_{1B}+θ_{2B})×λ_{B}/(4π) (In equation (15)), and, in regard to the light emitting device of which the color of emitted light is blue, an optical length L′_{0B} between a position, at which light is most intensively generated in the blue luminescent layer, and the reflective layer falls within a range that is expressed by 0.8×(2π·N_{0B}+θ_{1B})×λ_{B}/(4π)≦L′_{0B}≦1.2×(2π·N_{0B}+θ_{1B})×λ_{B}/(4π) (In equation (16)).

In this aspect as well, in each of the light emitting devices, it is possible to enhance the color purity around the wavelength λ within light that is emitted through the second electrode, and, hence, it is possible to increase the ratio of light having the wavelength λ to the light that is generated in the luminescent layer.

Yet another aspect of the invention provides an electronic apparatus. Because the electronic apparatus includes the above described organic electroluminescent device, the electronic apparatus is able to increase the color purity of light to be emitted and increase the ratio of emitted light to generated light. The above electronic apparatus, for example, includes various devices provided with the organic electroluminescent device as an image display device.

### BRIEF DESCRIPTION OF THE DRAWINGS

The invention will be described with reference to the accompanying drawings, wherein like numbers reference like elements.

FIG. 1 is a cross-sectional view that schematically shows an organic electroluminescent device according to a first embodiment of the invention.

FIG. 2 is a graph that shows the internal emission spectrum in a luminescent layer of the organic electroluminescent device shown in FIG. 1.

FIG. 3 is a graph that shows the advantageous effect according to the first embodiment.

FIG. 4 is another graph that shows the advantageous effect according to the first embodiment.

FIG. 5 is further another graph that shows the advantageous effect according to the first embodiment.

FIG. 6 is a cross-sectional view that schematically shows an organic electroluminescent device according to a second embodiment of the invention.

FIG. 7 is a cross-sectional view that schematically shows an organic electroluminescent device according to a third embodiment of the invention.

FIG. 8 is a perspective view that shows an electronic apparatus that employs the organic electroluminescent device according to the aspect of the invention.

FIG. 9 is a perspective view that shows another electronic apparatus that employs the organic electroluminescent device according to the aspect of the invention.

FIG. 10 is a perspective view that shows further another electronic apparatus that employs the organic electroluminescent device according to the aspect of the invention.

### DESCRIPTION OF EXEMPLARY EMBODIMENTS

Hereinafter, various embodiments according to the invention will be described with reference to the accompanying drawings. Note that, in the drawings, the ratio of dimension of each portion is appropriately varied from the actual one.

### First Embodiment

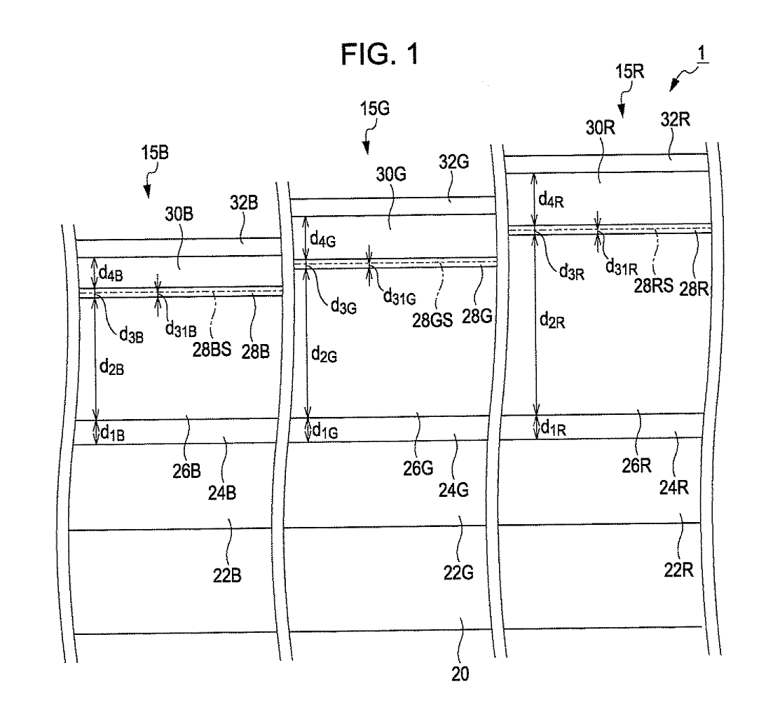

FIG. 1 is a cross-sectional view that schematically shows an organic electroluminescent device 1 according to a first embodiment of the invention. The organic electroluminescent (EL) device 1 includes a plurality of light emitting devices (pixels) 15 (15R, 15G, 15B) as shown in the drawing. The organic EL device 1 according to the present embodiment is used as a full-color image display device. A light emitting device 15R is a light emitting device of which the color of emitted light is red, a light emitting device 15G is a light emitting device of which the color of emitted light is green, and a light emitting device 15B is a light emitting device of which the color of emitted light is blue. In the drawing, only the three light emitting devices 15 are shown; however, a larger number of the light emitting devices than that shown in the drawing are actually provided. Hereinafter, the suffixes R, G, and B of the components respectively correspond to the light emitting devices 15R, 15G, and 15B.

The aspects of the invention may be applied not only to a bottom emission type but also to a top emission type. The organic EL device 1 shown in the drawing is a top emission type as an example. The organic EL device 1 has a substrate 20. The substrate 20 may be, for example, formed of a transparent material, such as glass, or may be, for example, formed of an opaque material, such as ceramics and metal.

However, FIG. 1 schematically shows the embodiment, and, although not shown in the drawing, TFTs (thin film transistors) and wirings that supply power to the pixels and an inorganic insulator layer that covers the TFTs and the wirings are arranged on the substrate 20. In addition, although not shown in the drawing, a known separation wall (separator) may be arranged.

The components of each light emitting device 15 on the substrate 20 include a reflective layer 22, a transparent electrode (first electrode) 24, a hole transport/injection layer 26, a luminescent layer 28, an electron transport/injection layer 30, and a transflective electrode (second electrode, transflective layer) 32. The reflective layer 22 is, for example, formed of a highly reflective metal, such as aluminum and chromium. The reflective layer 22 reflects light (which includes light from the luminescent layer 28), which is transmitted through the transparent electrode 24 and advances thereto, upward in the drawing, that is, toward the transflective electrode 32.

The transparent electrode 24 is, for example, formed of a transparent material, such as ITO (indium tin oxide), ZnO (zinc oxide) and IZO (indium zinc oxide). In the present embodiment, the transparent electrode 24 is a pixel electrode provided in each of the pixels (light emitting devices), and is, for example, an anode.

The hole transport/injection layer 26 has, for example, a double layer structure, and includes a hole injection layer arranged adjacent to the transparent electrode 24 and a hole transport layer arranged adjacent to the luminescent layer 28. The hole injection layer may be, for example, formed of a hole injection material, such as CuPc (copper phthalocyanine) or a product named “HI-406” produced by Idemitsu Kosan Co., Ltd. The hole transport layer may be, for example, formed of a hole transport material, such as NPD (N,N′-Bis(1-naphthyl)-N,N′diphenyl-4,4-biphenyl) or a product named “HT-320” produced by Idemitsu Kosan Co., Ltd. However, the hole transport/injection layer 26 may be a single layer that doubles the functions of the hole transport layer and the hole injection layer.

In the luminescent layer 28, positive holes derived from the transparent electrode 24 and electrons derived from the transflective electrode 32 are combined to thereby emit light. The luminescent layer 28 in the present embodiment is a single layer. Inside the luminescent layer 28, light is not generated with a uniform intensity, but light is generated most intensively at a certain plane (a plane perpendicular to the sheet of FIG. 1 and is parallel to the boundary between the luminescent layer 28 and the hole transport/injection layer 26 in the drawing) and light is generated weakly at the other positions. In FIG. 1, a hypothetical line 28RS indicates a plane at which light is most intensively generated inside the luminescent layer 28R of the light emitting device 15R, a hypothetical line 28GS indicates a plane at which light is most intensively generated inside the luminescent layer 28G of the light emitting device 15G, and a hypothetical line 28BS indicates a plane at which light is most intensively generated inside the luminescent layer 28B of the light emitting device 15B.

The electron transport/injection layer 30 has, for example, a double layer structure, and includes an electron transport layer arranged adjacent to the luminescent layer 28 and an electron injection layer arranged adjacent to the transflective electrode 32. The electron transport layer may be, for example, formed of an electron transport material, such as Alq3 (Tris8-quinolinolato aluminum complex). The electron injection layer may be, for example, formed of an electron injection material, such as LiF (lithium fluoride). However, the electron transport/injection layer 30 may be a single layer that doubles the functions of the electron transport layer and the electron injection layer. The electron transport/injection layer 30 may be provided with the same thickness in the plurality of pixels (light emitting devices) (that is, the electron transport/injection layers 30R, 30B, and 30G may have the same thickness).

The transflective electrode 32 is, for example, formed of a transflective metal material, such as MgAl, MgCu, MgAu and MgAg. In the present embodiment, the transflective electrode 32 is a common electrode that is provided commonly over the plurality of pixels (light emitting devices) and is, for example, a cathode. The transflective electrode 32 transmits a portion of light (which includes light from the luminescent layer 28), which is transmitted through the electron transport/injection layer 30 and advances thereto, upward in the drawing and reflects the remaining portion of light downward in the drawing, that is, toward the transparent electrode 24.

Although not shown in the drawing, in order to protect layers, such as the luminescent layer 28 of the organic EL device 1, against moisture and oxygen, the transflective electrode 32 may be covered with a known sealing film or a known sealing cap may be bonded to the substrate 20. In addition, when the organic EL device 1 is used as a color image display device, a color filter may be arranged on the side from which light is emitted in order to improve the color purity of emitted light. Note that providing a sealing film or a sealing cap and arranging a color filter may be not only employed in the present embodiment but also employed in the following other embodiments.

In the above structure, in a light emitting device, as an electric current flows between the transparent electrode 24 and the transflective electrode 32, the luminescent layer 28 generates light. Within light that is generated in the luminescent layer 28, a portion of light that advances downward in the drawing is reflected on the reflective layer 22 toward the transflective electrode 32. In addition, a portion of light that advances from the luminescent layer 28 upward in the drawing is transmitted through the transflective electrode 32 and the remaining portion of light is reflected toward the reflective layer 22. The above described reflection is repeatedly performed. Thus, in each of the light emitting devices 15, because of interference or resonance, a portion of light having a specific wavelength is intensified and a portion of light having the other wavelength is attenuated.

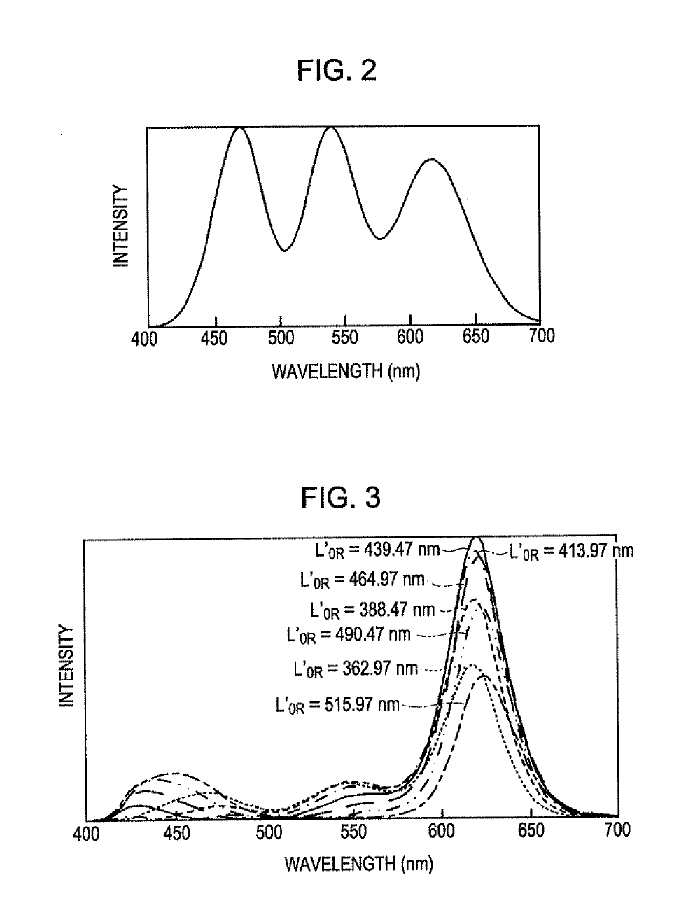

FIG. 2 is a graph that shows the internal emission spectrum in the luminescent layer 28. That is, FIG. 2 shows the emission spectrum of the luminescent layer 28 when interference or resonance of light is not applied in the light emitting device 15. As shown in FIG. 2, the luminescent layer 28, which is a single layer, emits white light having three peaks at 620 nm (which corresponds to red color), 540 nm (which corresponds to green color), and 470 nm (which corresponds to blue color). Note that the luminescent layers 28R, 28G, and 28B do not need to emit the same white light, but each of the luminescent layers may be configured to emit a selected luminescent color. For example, the luminescent layer 28R may emit red light that has a peak of emission spectrum at 620 nm, the luminescent layer 28G may emit green light that has a peak of emission spectrum at 540 nm, and the luminescent layer 28B may emit blue light that has a peak of emission spectrum at 470 nm.

Through the above described interference or resonance, in the light emitting device 15R, within white light that is generated in the luminescent layer 28, red color is intensified and then emitted from the transflective electrode 32. In the light emitting device 15G, within white light that is generated in the luminescent layer 28, green color is intensified and then emitted from the transflective electrode 32. In the light emitting device 15B, within white light that is generated in the luminescent layer 28, blue color is intensified and then emitted from the transflective electrode 32.

In order to emit light from the transflective electrode 32R so that only red color is intensified in the light emitting device 15R, theoretically, In equation (17) and In equation (18) are preferably satisfied, and, furthermore, Equation (19) and Equation (20) are preferably satisfied. In equation (17) and In equation (18) are derived from Equation (19) and Equation (20), which are theoretical equalities, with a tolerance of ±20%. The reason why the tolerance is given is that complex multiple reflection may actually occur.

0.8×(2π·N_{R}+θ_{1R}+θ_{2R})×λ_{R}/(4π)≦L′_{R}≦1.2×(2π·N_{R}+θ_{1R}+θ_{2R})×λ_{R}/(4π) (17)

0.8×(2π·N_{0R}+θ_{1R})×λ_{R}/(4π)≦L′_{0R}≦1.2×(2π·N_{0R}+θ_{1R})×λ_{R}/(4π) (18)

(2π·N_{R}+θ_{1R}+θ_{2R})×λ_{R}/(4π)=L′_{R} (19)

(2π·N_{0R}+θ_{1R})×λ_{R}/(4π)=L′_{0R} (20)

Here, λ_{R} denotes the peak wavelength of red light (λ_{R} may be, for example, set to 620 nm) that is emitted through the transflective electrode 32R, θ_{1R} denotes the phase shift (rad) of light having a wavelength λ_{R} when the light is reflected on the reflective layer 22R, θ_{2R} denotes the phase shift (rad) of light having a wavelength λ_{R} when the light is reflected on the transflective electrode 32R, N_{R} denotes an integer that is equal to or larger than 1, and N_{0R} denotes an integer that is equal to or larger than 1.

L′_{R} in In equation (17) and Equation (19) denotes an optical length in the light emitting device 15R between the reflective layer 22R and the transflective electrode 32R, and is expressed by Equation (21).

$${L}_{R}^{′} = {\sum }_{iR = 1}^{X} {n}_{iR} {d}_{iR} \qquad ( 21 )$$

In Equation (21), n_{iR} denotes the refractive index of a layer in the light emitting device 15R, and d_{iR} denotes the thickness of a layer in the light emitting device 15R. In Equation (21), iR ranges from 1 to X and denotes a layer between the reflective layer 22R and the transflective electrode 32R. X is the total number of these layers.

Specifically, in the embodiment shown in the drawing, the optical length L′_{R} in the light emitting device 15R between the reflective layer 22R and the transflective electrode 32R is expressed by Equation (22).

L′_{R}=n_{1R}·d_{1R}+n_{2R}·d_{2R}+n_{3R}·d_{3R}+n_{4R}·d_{4R} (22)

Here, n_{1R} denotes the refractive index of the transparent electrode 24R, and d_{iR} denotes the thickness of the transparent electrode 24R. n_{2R} denotes the refractive index of the hole transport/injection layer 26R, and d_{2R} denotes the thickness of the hole transport/injection layer 26R. n_{3R} denotes the refractive index of the luminescent layer 28R, and d_{3R} denotes the thickness of the luminescent layer 28R. n_{4R} denotes the refractive index of the electron transport/injection layer 30R, and d_{4R} denotes the thickness of the electron transport/injection layer 30R.

L′_{0R} in In equation (18) and Equation (20) denotes the optical length between the plane 28RS, at which light is most intensively generated in the luminescent layer 28R, and the reflective layer 22R, and is expressed by Equation (23).

$${L}_{0 R}^{′} = {n}_{NR} {d}_{N 1 R} + {\sum }_{iR = 1}^{M} {n}_{iR} {d}_{iR} \qquad ( 23 )$$

In Equation (23), n_{iR} denotes the refractive index of a layer in the light emitting device 15R, and d_{iR} denotes the thickness of a layer in the light emitting device 15R. In Equation (23), iR ranges from 1 to M and denotes a layer between the reflective layer 22R and the luminescent layer 28R. M is the total number of these layers. n_{NR} denotes the refractive index of the luminescent layer 28R, dN_{1R} denotes a distance between the plane 28RS, at which light is most intensively generated in the luminescent layer 28R, and the hole transport/injection layer 26R.

Specifically, in the embodiment shown in the drawing, the optical length L′_{0R} between the plane 28RS, at which light is most intensively generated in the luminescent layer 28R, and the reflective layer 22R is expressed by Equation (24).

L′_{0R}=n_{3R}·d_{31R}+n_{1R}·d_{1R}+n_{2R}·d_{2R} (24)

Here, d_{31R} denotes a distance between the plane 28RS, at which light is most intensively generated in the luminescent layer 28R, and the hole transport/injection layer 26R.

For example, it is given that the transparent electrode 24R is formed of ITO (of which the refractive index n_{1R} is 1.899 with respect to light having a wavelength of 620 nm) with the thickness d_{1R} of 30 nm, the refractive index n_{2R} of the hole transport/injection layer 26R is 1.7 and the thickness d_{2R} of the hole transport/injection layer 26R is 215 nm, the refractive index n_{3R} of the luminescent layer 28R is 1.7 and the thickness d_{3R} of the luminescent layer 28R is 10 nm, and the refractive index n_{4R} of the electron transport/injection layer 30R is 1.7 and the thickness d_{4R} of the electron transport/injection layer 30R is 65 nm. In this case, through Equation (21) and eventually through Equation (22), the optical length L′_{R} in the light emitting device 15R between the reflective layer 22R and the transflective electrode 32R is 549.97 nm.

In addition, it is given that the distance d_{31R} between the plane 28RS, at which light is most intensively generated in the luminescent layer 28R, and the hole transport/injection layer 26R is 5 nm. In this case, through Equation (23) and eventually through Equation (24), the optical length L′_{0R} in the light emitting device 15R between the plane 28RS, at which light is most intensively generated in the luminescent layer 28R, and the reflective layer 22R is 430.97 nm.

In addition, it is given that the phase shift θ_{1R} of light having a wavelength 620 nm, when the light is reflected on the reflective layer 22R, is 2.527 (rad), the phase shift θ_{2R} of light having a wavelength 620 nm, when the light is reflected on the transflective electrode 32R, is 2.390 (rad), N_{R} is 1, and N_{0R} is 1. In this case, (2π·N_{R}+θ_{1R}+θ_{2R})×λ_{R}/(4π)=552.60 nm, so that the relationship of In equation (17) is satisfied. In addition, in this case, (2π·N_{0R}+θ_{1R})×λ_{R}/(4π)=434.68 nm, so that the relationship of In equation (18) is satisfied.

In order to emit light from the transflective electrode 32 in such a manner that only green color is intensified in the light emitting device 15G, theoretically, In equation (25) and In equation (26) are preferably satisfied, and, furthermore, Equation (27) and Equation (28) are preferably satisfied. In equation (25) and In equation (26) are derived from Equation (27) and Equation (28), which are theoretical equalities, with a tolerance of ±20%. The reason why the tolerance is given is that complex multiple reflection may actually occur.

0.8×(2π·N_{G}+θ_{1G}+θ_{2G})×λ_{G}/(4π)≦L′_{G}≦1.2×(2π·N_{G}+θ_{1G}+θ_{2G})×λ_{G}/(4π) (25)

0.8×(2π·N_{0G}+θ_{1G})×λ_{G}/(4π)≦L′_{0G}≦1.2×(2π·N_{0G}+θ_{1G})×λ_{G}/(4π) (26)

(2π·N_{G}+θ_{1G}+θ_{2G})×λ_{G}/(4π)=L′_{G} (27)

(2π·N_{0G}+θ_{1G})×λ_{G}/(4π)=L′_{0G} (28)

Here, λ_{G} denotes the peak wavelength of green light (λ_{G} may be, for example, set to 540 nm) that is emitted through the transflective electrode 32G, θ_{1G} denotes the phase shift (rad) of light having a wavelength λ_{G} when the light is reflected on the reflective layer 22G, θ_{2G} denotes the phase shift (rad) of light having a wavelength λ_{G} when the light is reflected on the transflective electrode 32G, N_{G} denotes an integer that is equal to or larger than 1, and N_{0G} denotes an integer that is equal to or larger than 1.

L′_{G} in In equation (25) and Equation (27) denotes an optical length in the light emitting device 15G between the reflective layer 22G and the transflective electrode 32G, and is expressed by Equation (29).

$${L}_{G}^{′} = {\sum }_{iG = 1}^{X} {n}_{iG} {d}_{iG} \qquad ( 29 )$$

In Equation (29), n_{iG} denotes the refractive index of a layer in the light emitting device 15G, and d_{iG} denotes the thickness of a layer in the light emitting device 15G. In Equation (29), iG ranges from 1 to X and denotes a layer between the reflective layer 22G and the transflective electrode 32G. X is the total number of these layers.

Specifically, in the embodiment shown in the drawing, the optical length L′_{G} in the light emitting device 15G between the reflective layer 22G and the transflective electrode 32G is expressed by Equation (30).

L′_{G}=n_{1G}+d_{1G}+n_{2G}+d_{2G}+n_{3G}·d_{3G}+n_{4G}·d_{4G} (30)

Here, n_{1G} denotes the refractive index of the transparent electrode 24G, and d_{1G} denotes the thickness of the transparent electrode 24G. n_{2G} denotes the refractive index of the hole transport/injection layer 26G, and d_{2G} denotes the thickness of the hole transport/injection layer 26G. n_{3G} denotes the refractive index of the luminescent layer 28G, and d_{3G} denotes the thickness of the luminescent layer 28G. n_{4G} denotes the refractive index of the electron transport/injection layer 30G, and d_{4G} denotes the thickness of the electron transport/injection layer 30G.

L′_{0G} in In equation (26) and Equation (28) denotes the optical length between the plane 28GS, at which light is most intensively generated in the luminescent layer 28G, and the reflective layer 22G, and is expressed by Equation (31).

$${L}_{0 G}^{′} = {n}_{NG} {d}_{N 1 G} + {\sum }_{iG = 1}^{M} {n}_{iG} {d}_{iG} \qquad ( 31 )$$

In Equation (31), n_{iG} denotes the refractive index of a layer in the light emitting device 15G, and d_{iG} denotes the thickness of a layer in the light emitting device 15G. In Equation (31), iG ranges from 1 to M and denotes a layer between the reflective layer 22G and the luminescent layer 28G. M is the total number of these layers. n_{NG} denotes the refractive index of the luminescent layer 28G, d_{N1G} denotes a distance between the plane 28GS, at which light is most intensively generated in the luminescent layer 28G, and the hole transport/injection layer 26G.

Specifically, in the embodiment shown in the drawing, the optical length L′_{0G} between the plane 28GS, at which light is most intensively generated in the luminescent layer 28G, and the reflective layer 22G is expressed by Equation (32).

L′_{0G}=n_{3G}·d_{31G}+n_{1G}·d_{1G}+n_{2G}·d_{2G} (32)

Here, d_{31G} denotes a distance between the plane 28GS, at which light is most intensively generated in the luminescent layer 28G, and the hole transport/injection layer 26G.

For example, it is given that the transparent electrode 24G is formed of ITO (of which the refractive index n_{1G} is 1.972 with respect to light having a wavelength of 540 nm) with the thickness d_{1G} of 30 nm, the refractive index n_{2G} of the hole transport/injection layer 26G is 1.7 and the thickness d_{2G} of the hole transport/injection layer 26G is 178 nm, the refractive index n_{3G} of the luminescent layer 28G is 1.7 and the thickness d_{3G} of the luminescent layer 28G is 10 nm, and the refractive index n_{4G} of the electron transport/injection layer 30G is 1.7 and the thickness d_{4G} of the electron transport/injection layer 30G is 53 nm. In this case, through Equation (29) and eventually through Equation (30), the optical length L′_{G} in the light emitting device 15G between the reflective layer 22G and the transflective electrode 32G is 468.86 nm.

In addition, it is given that the distance d_{31G} between the plane 28GS, at which light is most intensively generated in the luminescent layer 28G, and the hole transport/injection layer 26G is 5 nm. In this case, through Equation (31) and eventually through Equation (32), the optical length L′_{0G} in the light emitting device 15G between the plane 28GS, at which light is most intensively generated in the luminescent layer 28G, and the reflective layer 22G is 370.26 nm.

In addition, it is given that the phase shift θ_{1G} of light having a wavelength 540 nm, when the light is reflected on the reflective layer 22G, is 2.445 (rad), the phase shift θ_{2G} of light having a wavelength 540 nm, when the light is reflected on the transflective electrode 32G, is 2.278 (rad), N_{G} is 1, and N_{0G} is 1, In this case, (2π·N_{G}+θ_{1G}+θ_{2G})×λ_{G}/(4π)=472.96 nm, so that the relationship of In equation (25) is satisfied. In addition, in this case, (2π·N_{0G}+θ_{1G})×λ_{G}/(4π)=375.067 nm, so that the relationship of In equation (26) is satisfied.

In order to emit light from the transflective electrode 32 in such a manner that only blue color is intensified in the light emitting device 15B, theoretically, In equation (33) and In equation (34) are preferably satisfied, and, furthermore, Equation (35) and Equation (36) are preferably satisfied. In equation (33) and In equation (34) are derived from Equation (35) and Equation (36), which are theoretical equalities, with a tolerance of ±20%. The reason why the tolerance is given is that complex multiple reflection may actually occur.

0.8×(2π·N_{B}+θ_{1B}+θ_{2B})×λ_{B}/(4π)≦L′_{B}≦1.2×(2π·N_{B}+θ_{1B}+θ_{2B})×λ_{B}/(4π) (33)

0.8×(2π·N_{0B}+θ_{1B})×λ_{B}/(4π)≦L′_{0B}≦1.2×(2π·N_{0B}+θ_{1B})×λ_{B}/(4π) (34)

(2π·N_{B}+θ_{1B}+θ_{2B})×λ_{B}/(4π)=L′_{B} (35)

(2π·N_{0B}+θ_{1B})×λ_{B}/(4π)=L′_{0B} (36)

Here, λ_{B} denotes the peak wavelength of blue light (λ_{B} may be, for example, set to 470 nm) that is emitted through the transflective electrode 32B, θ_{1B} denotes the phase shift (rad) of light having a wavelength λ_{B} when the light is reflected on the reflective layer 22B, θ_{2B} denotes the phase shift (rad) of light having a wavelength λ_{B} when the light is reflected on the transflective electrode 32B, N_{B} denotes an integer that is equal to or larger than 1, and N_{0B} denotes an integer that is equal to or larger than 1.

L′_{B} in In equation (33) and Equation (35) denotes an optical length in the light emitting device 15B between the reflective layer 22B and the transflective electrode 32B, and is expressed by Equation (37)

$${L}_{B}^{′} = {\sum }_{iB = 1}^{x} {n}_{iB} {d}_{iB} \qquad ( 37 )$$

In Equation (37), n_{iB} denotes the refractive index of a layer in the light emitting device 15B, and d_{iB} denotes the thickness of a layer in the light emitting device 15. In Equation (37), iB ranges from 1 to X and denotes a layer between the reflective layer 22B and the transflective electrode 32B. X is the total number of these layers.

Specifically, in the embodiment shown in the drawing, the optical length L′_{B} in the light emitting device 15B between the reflective layer 22B and the transflective electrode 32B is expressed by Equation (38).

L′_{B}=n_{1B}·d_{1B}+n_{2B}·d_{2B}+n_{3B}·d_{3B}+n_{4B}·d_{4B} (38)

Here, n_{1B} denotes the refractive index of the transparent electrode 24B, and d_{1B} denotes the thickness of the transparent electrode 24B. n_{2B} denotes the refractive index of the hole transport/injection layer 26B, and d_{2B} denotes the thickness of the hole transport/injection layer 26B. n_{3B} denotes the refractive index of the luminescent layer 28B, and d_{3B} denotes the thickness of the luminescent layer 28B. n_{4B} denotes the refractive index of the electron transport/injection layer 30B, and d_{4B} denotes the thickness of the electron transport/injection layer 30B.

L′_{0B} in In equation (34) and Equation (36) denotes the optical length between the plane 28BS, at which light is most intensively generated in the luminescent layer 28B, and the reflective layer 22B, and is expressed by Equation (39).

$${L}_{0 B}^{′} = {n}_{NB} {d}_{N 1 B} + {\sum }_{iB = 1}^{M} {n}_{iB} {d}_{iB} \qquad ( 39 )$$

In Equation (39), n_{iB} denotes the refractive index of a layer in the light emitting device 15B, and d_{iB} denotes the thickness of a layer in the light emitting device 15B. In Equation (39), iB ranges from 1 to M and denotes a layer between the reflective layer 22B and the luminescent layer 28B. M is the total number of these layers. n_{NB} denotes the refractive index of the luminescent layer 28B, d_{N1B} denotes a distance between the plane 28BS, at which light is most intensively generated in the luminescent layer 28B, and the hole transport/injection layer 26B.

Specifically, in the embodiment shown in the drawing, the optical length L′_{0B} between the plane 28BS, at which light is most intensively generated in the luminescent layer 28B, and the reflective layer 22B is expressed by Equation (40).

L′_{0B}=n_{3B}·d_{31B}+n_{1B}·d_{1B}+n_{2B}·d_{2B} (40)

Here, d_{31B} denotes a distance between the plane 28BS, at which light is most intensively generated in the luminescent layer 28B, and the hole transport/injection layer 26B.

For example, it is given that the transparent electrode 24B is formed of ITO (of which the refractive index n_{1B} is 2.043 with respect to light having a wavelength of 470 nm) with the thickness d_{1B} of 30 nm, the refractive index n_{2B} of the hole transport/injection layer 26B is 1.7 and the thickness d_{2B} of the hole transport/injection layer 26B is 146 am, the refractive index n_{3B} of the luminescent layer 28B is 1.7 and the thickness d_{3B} of the luminescent layer 28B is 10 nm, and the refractive index n_{4B} of the electron transport/injection layer 30B is 1.7 and the thickness d_{4B} of the electron transport/injection layer 30B is 42 nm. In this case, through Equation (37) and eventually through Equation (38), the optical length L′_{B} in the light emitting device 15B between the reflective layer 22B and the transflective electrode 32B is 397.89 nm.

In addition, it is given that the distance d_{31B} between the plane 28BS, at which light is most intensively generated in the luminescent layer 28B, and the hole transport/injection layer 26B is 5 nm. In this case, through Equation (39) and eventually through Equation (40), the optical length L′_{0B} in the light emitting device 15B between the plane 28BS, at which light is most intensively generated in the luminescent layer 28B, and the reflective layer 22B is 317.99 nm.

In addition, it is given that the phase shift θ_{1B} of light having a wavelength 470 nm, when the light is reflected on the reflective layer 22B, is 2.343 (rad), the phase shift θ_{2B} of light having a wavelength 470 nm, when the light is reflected on the transflective electrode 32B, is 2.154 (rad), N_{B} is 1, and N_{0B} is 1. In this case, (2π·N_{B}+θ_{1B}+θ_{2B})×λ_{B}/(4π)=403.19 nm, so that the relationship of In equation (33) is satisfied. In addition, in this case, (2π·N_{0B}+θ_{1B})×λ_{B}/(4π)=322.63 nm, so that the relationship of In equation (34) is satisfied.

In summary, it is preferable that, in each of the light emitting devices 15, the optical length L′ between the reflective layer 22 and the transflective electrode 32 falls within the range expressed by In equation (41), and in each of the light emitting devices 15, the optical length L′0 between the position, that is, the plane, at which light is most intensively generated in the luminescent layer 28, and the reflective layer 22 falls within the range expressed by In equation (42).

0.8×(2π·N+θ1+θ2)×λ/(4π)≦L′≦1.2×(2π·N+θ1+θ2)×λ/(4π) (41)

0.8×(2π·N0+θ1)×λ/(4π)≦L′0≦1.2×(2π·N0+θ1)×λ/(4π) (42)

Here, λ denotes the peak wavelength of light that is emitted through the transflective electrode 32, θ1 denotes the phase shift (rad) of light having a wavelength λ when the light is reflected on the reflective layer 22, θ2 denotes the phase shift (rad) of light having a wavelength λ when the light is reflected on the transflective electrode 32, N denotes an integer that is equal to or larger than 1, and N0 denotes an integer that is equal to or larger than 1.

In order to ascertain whether the derived optical lengths L′_{0R}, L′_{0G}, and L′_{0B} are optimal, simulation was performed. In the simulation, the spectra were obtained in such a manner that the optical lengths L′_{R}, L′_{G}, and L′_{B} were fixed and the optical lengths L′_{0R}, L′_{0G}, and L′_{0B} were varied.

FIG. 3 is a graph that shows the spectra that were obtained in such a manner that, in the light emitting device 15R, the optical length L′_{R} was fixed to 549.97 nm (which is the result obtained through Equation (22)) and the optical length L′_{0R} was varied. Specifically, the optical length L′_{0R} was varied by varying the thickness d_{2R} of the hole transport/injection layer 26R, and the optical length L′_{R} was maintained at a fixed value in such a manner that the variation in the thickness d_{2R} of the hole transport/injection layer 26R was cancelled by a variation in the thickness d_{4R} of the electron transport/injection layer 30R.

As is apparent from FIG. 3, the spectrum, of which L′_{0R} is 439.47 nm, is the best, and this result satisfies the relationship of In equation (18).

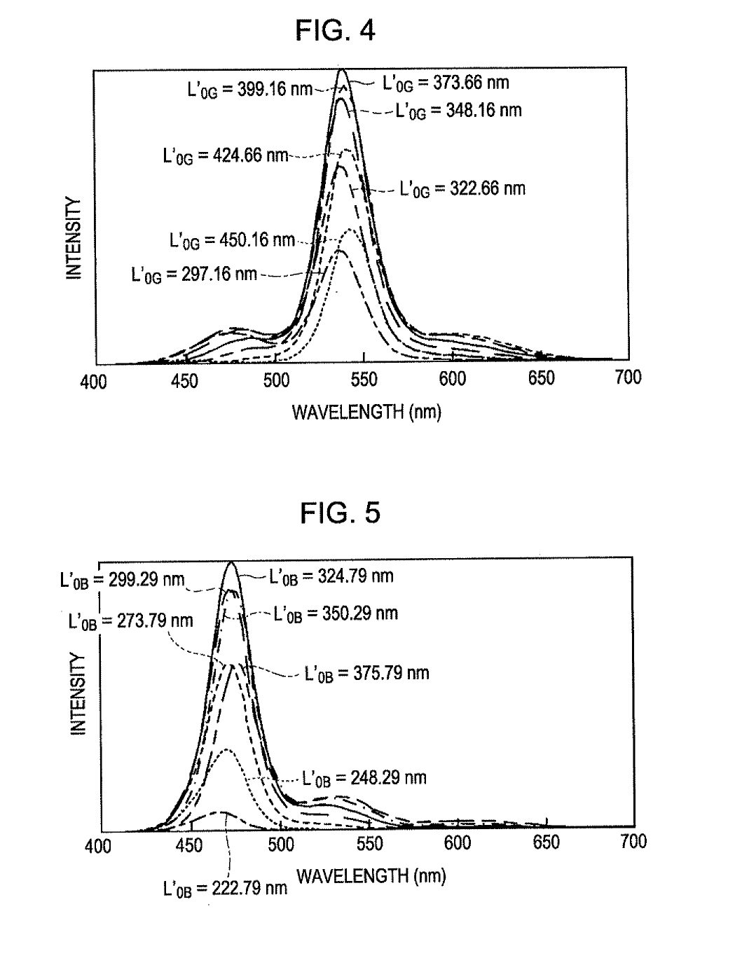

FIG. 4 is a graph that shows the spectra that were obtained in such a manner that, in the light emitting device 15G, the optical length L′_{G} was fixed to 468.86 nm (which is the result obtained through Equation (30)) and the optical length L′_{0G} was varied. Specifically, the optical length L′_{0G} was varied by varying the thickness d_{2G} of the hole transport/injection layer 26G, and the optical length L′_{G} was maintained at a fixed value in such a manner that the variation in the thickness d_{2G} of the hole transport/injection layer 26G was cancelled by a variation in the thickness d_{4G} of the electron transport/injection layer 30G.

As is apparent from FIG. 4, the spectrum, of which L′_{0G} is 373.66 nm, is the best, and this result satisfies the relationship of In equation (26).

FIG. 5 is a graph that shows the spectra that were obtained in such a manner that, in the light emitting device 15B, the optical length L′_{B} was fixed to 397.89 nm (which is the result obtained through Equation (38)) and the optical length L′_{0B} was varied. Specifically, the optical length L′_{0B} was varied by varying the thickness d_{2B} of the hole transport/injection layer 26B, and the optical length L′_{B} was maintained at a fixed value in such a manner that the variation in the thickness d_{2B} of the hole transport/injection layer 26B was cancelled by a variation in the thickness d_{4B} of the electron transport/injection layer 30B.

As is apparent from FIG. 5, the spectrum, of which L′_{0B} is 324.79 nm, is the best, and this result satisfies the relationship of In equation (34).

### Second Embodiment

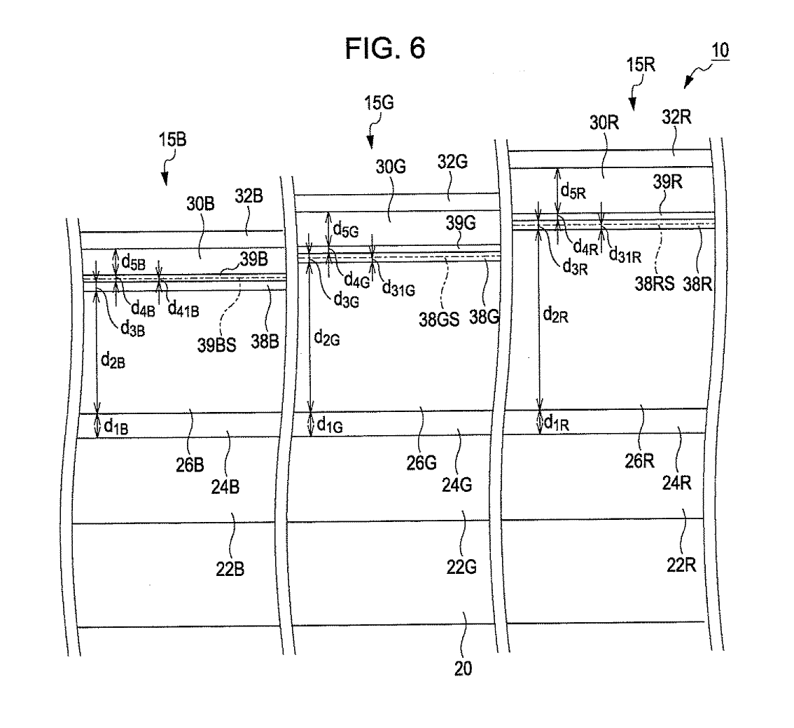

FIG. 6 is a cross-sectional view that schematically shows an organic electroluminescent device 10 according to a second embodiment of the invention. The same reference signs are used in FIG. 6 to indicate the components that are common to those of the first embodiment, and the description thereof will not be repeated in detail. The organic EL device 10 according to the second embodiment basically has the similar structure to that of the organic EL device 1 according to the first embodiment. The modification in regard to the first embodiment may also be applied to the second embodiment.

However, the first embodiment has the single luminescent layer 28, whereas the second embodiment shown in FIG. 6 has a pair of laminated luminescent layers 38 and 39 that are arranged between the hole transport/injection layer 26 and the electron transport/injection layer 30. The luminescent layer 38 is a first luminescent layer of which generated light has a peak intensity at a wavelength corresponding to yellow color, orange color, or red color. That is, as the first luminescent layer 38 is energized, the first luminescent layer 38 generates light (which includes a light component having a wavelength corresponding to red and green) having a peak intensity at a wavelength corresponding to yellow color, orange color or red color. On the other hand, the luminescent layer 39 is a second luminescent layer of which generated light has a peak intensity at a wavelength corresponding to cyan color or blue color. That is, as the second luminescent layer 39 is energized, the second luminescent layer 39 generates light (which includes a light component having a wavelength corresponding to blue and green) having a peak intensity at a wavelength corresponding to cyan color or blue color. In FIG. 6, the first luminescent layer 38 is arranged adjacent to the hole transport/injection layer 26, and the second luminescent layer 39 is arranged adjacent to the electron transport/injection layer 30; however, the order, that is, the positions of the luminescent layers 38 and 39 may be interchanged.

Because the two color luminescent layers 38 and 39 are laminated as described above, as the light emitting device 15 is energized, the luminescent layers 38 and 39 of the light emitting device 15 may cooperate to generate white light. However, in each of the light emitting devices 15, because of interference or resonance, a portion of light having a specific wavelength is intensified and a portion of light having the other wavelength is attenuated. That is, in the light emitting device 15R, within white light that is generated in the luminescent layers 38 and 39 (particularly, light generated in the first luminescent layer 38), red color is intensified and then emitted from the transflective electrode 32. In the light emitting device 15G, within white light that is generated in the luminescent layers 38 and 39, green color is intensified and then emitted from the transflective electrode 32. In the light emitting device 15B, within white light that is generated in the luminescent layers 38 and 39 (particularly, light generated in the second luminescent layer 39), blue color is intensified and then emitted from the transflective electrode 32.

Inside each of the luminescent layers 38 and 39, light is not generated with a uniform intensity, but light is generated most intensively at a certain plane (a plane perpendicular to the sheet of FIG. 6 and is parallel to the boundary between the luminescent layer 38 and the hole transport/injection layer 26 in the drawing) and light is generated weakly at the other positions. In FIG. 6, a hypothetical line 38RS indicates a plane at which light is most intensively generated inside the luminescent layer 38R of the light emitting device 15R, a hypothetical line 38GS indicates a plane at which light is most intensively generated inside the luminescent layer 38G of the light emitting device 15G, and a hypothetical line 39BS indicates a plane at which light is most intensively generated inside the luminescent layer 39B of the light emitting device 15B.

In order to emit light from the transflective electrode 32R so that only red color is intensified in the light emitting device 15R, theoretically, In equation (43) and In equation (44) are preferably satisfied, and, furthermore, Equation (45) and Equation (46) are preferably satisfied. In equation (43) and In equation (44) are derived from Equation (45) and Equation (46), which are theoretical equalities, with a tolerance of ±20%. The reason why the tolerance is given is that complex multiple reflection may actually occur.

0.8×(2π·N_{R}+θ_{1R}+θ_{2R})×λ_{R}/(4π)≦L′_{R}≦1.2×(2π·N_{R}+θ_{1R}+θ_{2R})×λ_{R}/(4π) (43 )

0.8×(2π·N_{0R}+θ_{1R})×λ_{R}/(4π)≦L′_{0R}≦1.2×(2π·N_{0R}+θ_{1R})×λ_{R}/(4π) (44)

(2π·N_{R}+θ_{1R}+θ_{2R})×λ_{R}/(4π)=L′_{R} (45)

(2π·N_{0R}+θ_{1R})×λ_{R}/(4π)=L′_{0R} (46)

Here, λ_{R} denotes the peak wavelength of red light (λ_{R} may be, for example, set to 620 nm) that is emitted through the transflective electrode 32R, θ_{1R} denotes the phase shift (rad) of light having a wavelength λ_{R} when the light is reflected on the reflective layer 22R, θ_{2R} denotes the phase shift (rad) of light having a wavelength λ_{R} when the light is reflected on the transflective electrode 32R, N_{R} denotes an integer that is equal to or larger than 1, and N_{0R} denotes an integer that is equal to or larger than 1.

L′_{R} in In equation (43) and Equation (45) denotes an optical length in the light emitting device 15R between the reflective layer 22R and the transflective electrode 32R, and is expressed by Equation (47).

$${L}_{R}^{′} = {\sum }_{iR = 1}^{X} {n}_{iR} {d}_{iR} \qquad ( 47 )$$

In Equation (47), n_{iR} denotes the refractive index of a layer in the light emitting device 15R, and d_{iR} denotes the thickness of a layer in the light emitting device 15R. In Equation (47), iR ranges from 1 to X and denotes a layer between the reflective layer 22R and the transflective electrode 32R. X is the total number of these layers.

Specifically, in the embodiment shown in the drawing, the optical length L′_{R} in the light emitting device 15R between the reflective layer 22R and the transflective electrode 32R is expressed by Equation (48).

L′_{R}=n_{1R}·d_{1R}+n_{2R}·d_{2R}+n_{3R}·d_{3R}+n_{4R}·d_{4R}+n_{5R}·d_{5R} (48)

Here, n_{1R} denotes the refractive index of the transparent electrode 24R, and d_{1R} denotes the thickness of the transparent electrode 24R. n_{2R} denotes the refractive index of the hole transport/injection layer 26R, and d_{2R} denotes the thickness of the hole transport/injection layer 26R. n_{3R} denotes the refractive index of the first luminescent layer 38R, and d_{3R} denotes the thickness of the first luminescent layer 38R. n_{4R} denotes the refractive index of the second luminescent layer 39R, and d_{4R} denotes the thickness of the second luminescent layer 39R. n_{5R} denotes the refractive index of the electron transport/injection layer 30R, and d_{5R} denotes the thickness of the electron transport/injection layer 30R.

L′_{0R} in In equation (44) and Equation (46) denotes the optical length between the plane 38RS, at which light is most intensively generated in the first luminescent layer 38R, and the reflective layer 22R, and is expressed by Equation (49).

$${L}_{0 R}^{′} = {n}_{NR} {d}_{N 1 R} + {\sum }_{iR = 1}^{M} {n}_{iR} {d}_{iR} \qquad ( 49 )$$

In Equation (49), n_{iR} denotes the refractive index of a layer in the light emitting device 15R, and d_{iR} denotes the thickness of a layer in the light emitting device 15R. In Equation (49), iR ranges from 1 to N and denotes a layer between the reflective layer 22R and the first luminescent layer 38R. X is the total number of these layers. n_{NR} denotes the refractive index of the first luminescent layer 38R, d_{N1R} denotes a distance between the plane 38RS, at which light is most intensively generated in the first luminescent layer 38R, and the hole transport/injection layer 26R.

Specifically, in the embodiment shown in the drawing, the optical length L′_{0R} between the plane 38RS, at which light is most intensively generated in the first luminescent layer 38R, and the reflective layer 22R is expressed by Equation (50).

L′_{0R}=n_{3R}·d_{31R}+n_{1R}·d_{1R}+n_{2R}·d_{2R} (50)

Here, d_{31R} denotes a distance between the plane 38RS, at which light is most intensively generated in the first luminescent layer 38R, and the hole transport/injection layer 26R.

In order to emit light from the transflective electrode 32 in such a manner that only green color is intensified in the light emitting device 15G, theoretically, In equation (51) and In equation (52) are preferably satisfied, and, furthermore, Equation (53) and Equation (54) are preferably satisfied. In equation (51) and In equation (52) are derived from Equation (53) and Equation (54), which are theoretical equalities, with a tolerance of ±20%. The reason why the tolerance is given is that complex multiple reflection may actually occur.

0.8×(2π·N_{G}+θ_{1G}+θ_{2G})×λ_{G}/(4π)≦L′_{G}≦1.2×(2π·N_{G}+θ_{1G}+θ_{2G})×λ_{G}/(4π) (51)

0.8×(2π·N_{0G}+θ_{1G})×λ_{G}/(4π)≦L′_{0G}≦1.2×(2π·N_{0G}+θ_{1G})×λ_{G}/(4π) (52)

(2π·N_{G}+θ_{1G}+θ_{2G})×λ_{G}/(4π)=L′_{G} (53)

(2π·N_{0G}+θ_{1G})×λ_{G}/(4π)=L′_{0G} (54)

Here, λ_{G} denotes the peak wavelength of green light (λ_{G} may be, for example, set to 540 nm) that is emitted through the transflective electrode 32G, θ_{1G} denotes the phase shift (rad) of light having a wavelength λ_{G} when the light is reflected on the reflective layer 22G, θ_{2G} denotes the phase shift (rad) of light having a wavelength λ_{G} when the light is reflected on the transflective electrode 32G, N_{G} denotes an integer that is equal to or larger than 1, and N_{0G} denotes an integer that is equal to or larger than 1.

L′_{G} in In equation (51) and Equation (53) denotes an optical length in the light emitting device 15G between the reflective layer 22G and the transflective electrode 32G, and is expressed by Equation (55).

$${L}_{G}^{′} = {\sum }_{iG = 1}^{X} {n}_{iG} {d}_{iG} \qquad ( 55 )$$

In Equation (55), n_{iG} denotes the refractive index of a layer in the light emitting device 15G, and d_{iG} denotes the thickness of a layer in the light emitting device 15G. In Equation (55), iG ranges from 1 to X and denotes a layer between the reflective layer 22G and the transflective electrode 32G. X is the total number of these layers.

Specifically, in the embodiment shown in the drawing, the optical length L′_{G} in the light emitting device 15G between the reflective layer 22G and the transflective electrode 32G is expressed by Equation (56).

L′_{G}=n_{1G}·d_{1G}+n_{2G}·d_{2G}+n_{3G}·d_{3G}+n_{4G}·d_{4G}+n_{5G}·d_{5G} (56)

Here, n_{1G} denotes the refractive index of the transparent electrode 24G, and d_{1G} denotes the thickness of the transparent electrode 24G. n_{2G} denotes the refractive index of the hole transport/injection layer 26G, and d_{2G} denotes the thickness of the hole transport/injection layer 26G. n_{3G} denotes the refractive index of the first luminescent layer 38G, and d_{3G} denotes the thickness of the first luminescent layer 38G. n_{4G} denotes the refractive index of the second luminescent layer 39G, and d_{4G} denotes the thickness of the second luminescent layer 39G. n_{5G} denotes the refractive index of the electron transport/injection layer 30G, and d_{5G} denotes the thickness of the electron transport/injection layer 30G.

L′_{0G} in In equation (52) and Equation (54) denotes the optical length between the plane 38GS, at which light is most intensively generated in the first luminescent layer 38G, and the reflective layer 22G, and is expressed by Equation (57).

$${L}_{0 G}^{′} = {n}_{NG} {d}_{N 1 G} + {\sum }_{iG = 1}^{M} {n}_{iG} {d}_{iG} \qquad ( 57 )$$

In Equation (57), n_{iG} denotes the refractive index of a layer in the light emitting device 15G, and d_{iG} denotes the thickness of a layer in the light emitting device 15G. In Equation (57), iG ranges from 1 to M and denotes a layer between the reflective layer 22G and the first luminescent layer 38G. N is the total number of these layers. n_{NG} denotes the refractive index of the first luminescent layer 38G, d_{N1G} denotes a distance between the plane 38GS, at which light is most intensively generated in the first luminescent layer 38G, and the hole transport/injection layer 26G.

Specifically, in the embodiment shown in the drawing, the optical length L′_{0G} between the plane 38GS, at which light is most intensively generated in the first luminescent layer 38G, and the reflective layer 22G is expressed by Equation (58).

L′_{0G}=n_{3G}·d_{31G}+n_{1G}·d_{1G}+n_{2G}·d_{2G} (58)

Here, d_{31G} denotes a distance between the plane 38GS, at which light is most intensively generated in the first luminescent layer 38G, and the hole transport/injection layer 26G.

In order to emit light from the transflective electrode 32 in such a manner that only blue color is intensified in the light emitting device 15B, theoretically, In equation (59) and In equation (60) are preferably satisfied, and, furthermore, Equation (61) and Equation (62) are preferably satisfied. In equation (59) and In equation (60) are derived from Equation (61) and Equation (62), which are theoretical equalities, with a tolerance of ±20%. The reason why the tolerance is given is that complex multiple reflection may actually occur.

0.8×(2π·N_{B}+θ_{1B}+θ_{2B})×λ_{B}/(4π)≦L′_{B}≦1.2×(2π·N_{B}+θ_{1B}+θ_{2B})×λ_{B}/(4π) (59)

0.8×(2π·N_{0B}+θ_{1B})×λ_{B}/(4π)≦L′_{0B}≦1.2×(2π·N_{0B}+θ_{1B})×λ_{B}/(4π) (60)

(2π·N_{B}+θ_{1B}+θ_{2B})×λ_{B}/(4π)=L′_{B} (61)

(2π·N_{0B}+θ_{1B})×λ_{B}/(4π)=L′_{0B} (62)

Here, λ_{B} denotes the peak wavelength of blue light (λ_{B} may be, for example, set to 470 nm) that is emitted through the transflective electrode 32B, θ_{1B} denotes the phase shift (rad) of light having a wavelength λ_{B} when the light is reflected on the reflective layer 22B, θ_{2B} denotes the phase shift (rad) of light having a wavelength λ_{B} when the light is reflected on the transflective electrode 32B, N_{B} denotes an integer that is equal to or larger than 1, and N_{0B} denotes an integer that is equal to or larger than 1.

L′_{B} in In equation (59) and Equation (61) denotes an optical length in the light emitting device 15B between the reflective layer 22B and the transflective electrode 32B, and is expressed by Equation (63).

$${L}_{B}^{′} = {\sum }_{iB = 1}^{X} {n}_{iB} {d}_{iB} \qquad ( 63 )$$

In Equation (63), n_{iB} denotes the refractive index of a layer in the light emitting device 15B, and d_{iB} denotes the thickness of a layer in the light emitting device 15B. In Equation (63), iB ranges from 1 to X and denotes a layer between the reflective layer 22B and the transflective electrode 32B. X is the total number of these layers.

Specifically, in the embodiment shown in the drawing, the optical length L′_{B} in the light emitting device 15B between the reflective layer 22B and the transflective electrode 32B is expressed by Equation (64).

L′_{B}=n_{1B}·d_{1B}+n_{2B}·d_{2B}+n_{3B}·d_{3B}+n_{4B}·d_{4B}+n_{5B}·d_{5B} (64)

Here, n_{1B} denotes the refractive index of the transparent electrode 24B, and d_{1B} denotes the thickness of the transparent electrode 24B. n_{2B} denotes the refractive index of the hole transport/injection layer 26B, and d_{2B} denotes the thickness of the hole transport/injection layer 26B. n_{3B} denotes the refractive index of the first luminescent layer 38B, and d_{3B} denotes the thickness of the first luminescent layer 38B. n_{4B} denotes the refractive index of the second luminescent layer 39B, and d_{4B} denotes the thickness of the second luminescent layer 39B. n_{5B} denotes the refractive index of the electron transport/injection layer 30B, and d_{5B} denotes the thickness of the electron transport/injection layer 30B.

L′_{0B} in In equation (60) and Equation (62) denotes the optical length between the plane 39BS, at which light is most intensively generated in the second luminescent layer 39B, and the reflective layer 22B, and is expressed by Equation (65).

$${L}_{0 B}^{′} = {n}_{NB} {d}_{N 1 B} + {\sum }_{iB = 1}^{M} {n}_{iB} {d}_{iB} \qquad ( 65 )$$

In Equation (65), n_{iB} denotes the refractive index of a layer in the light emitting device 15B, and d_{iB} denotes the thickness of a layer in the light emitting device 15B. In Equation (65), iB ranges from 1 to M and denotes a layer between the reflective layer 22B and the second luminescent layer 39B. M is the total number of these layers. n_{NB} denotes the refractive index of the second luminescent layer 38B, d_{N1B} denotes a distance between the plane 39BS, at which light is most intensively generated in the second luminescent layer 39B, and the first luminescent layer 38B.

Specifically, in the embodiment shown in the drawing, the optical length L′_{0B} between the plane 39BS, at which light is most intensively generated in the second luminescent layer 39B, and the reflective layer 22B is expressed by Equation (66).

L′_{0B}=n_{4B}·d_{41B}+n_{1B}·d_{1B}+n_{2B}·d_{2B}+n_{3B}·d_{3B} (66)

Here, d_{41B} denotes a distance between the plane 39BS, at which light is most intensively generated in the second luminescent layer 39B, and the first luminescent layer 38B.

In the second embodiment, the optical length L′_{0G} in the light emitting device 15G of which the color of emitted light is green is an optical length between the plane 38GS, at which light is most intensively generated in the first luminescent layer 38G, and the reflective layer 22G. However, the optical length L′_{0G} may be an optical length between the plane, at which light is most intensively generated in the second luminescent layer 39G, and the reflective layer 22G. For example, when the intensity of a component having a wavelength corresponding to green color within light generated in the first luminescent layer 38G is higher than that of a component having a wavelength corresponding to green color within light generated in the second luminescent layer 39G, the optical length L′_{0G} is preferably an optical length between the plane 38GS, at which light is most intensively generated in the first luminescent layer 38G, and the reflective layer 22G. In the reverse case, the optical length L′_{0G} is preferably an optical length between the planer at which light is most intensively generated in the second luminescent layer 39G, and the reflective layer 22G.

### Third Embodiment

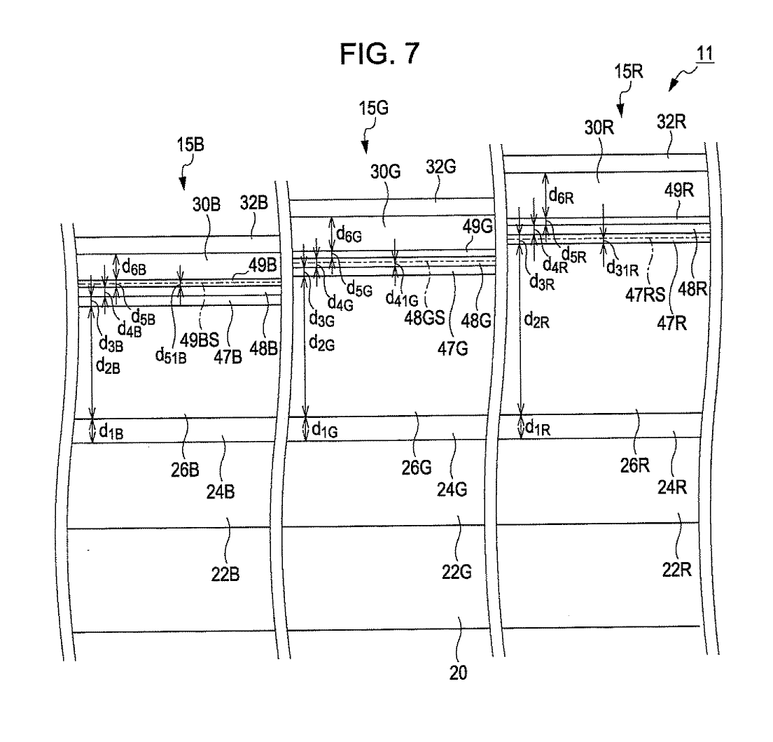

FIG. 7 is a cross-sectional view that schematically shows an organic electroluminescent device 11 according to a third embodiment of the invention. The same reference signs are used in FIG. 7 to indicate the components that are common to those of the first embodiment, and the description thereof will not be repeated in detail. The organic EL device 11 according to the third embodiment basically has the similar structure to that of the organic EL device 1 according to the first embodiment. The modification in regard to the first embodiment may also be applied to the third embodiment.

The third embodiment shown in FIG. 7 has triple laminated luminescent layers 47, 43, and 49 that are arranged between the hole transport/injection layer 26 and the electron transport/injection layer 30. The luminescent layer 47 is a red luminescent layer of which generated light has a peak intensity at a wavelength corresponding to red color. That is, as the red luminescent layer 47 is energized, the red luminescent layer 47 generates light having a peak intensity at a wavelength corresponding to red color. The luminescent layer 48 is a green luminescent layer of which generated light has a peak intensity at a wavelength corresponding to green color. That is, as the green luminescent layer 48 is energized, the green luminescent layer 48 generates light having a peak intensity at a wavelength corresponding to green color. The luminescent layer 49 is a blue luminescent layer of which generated light has a peak intensity at a wavelength corresponding to blue color. That is, as the blue luminescent layer 49 is energized, the blue luminescent layer 49 generates light having a peak intensity at a wavelength corresponding to blue color. In FIG. 7, the red luminescent layer 47 is arranged adjacent to the hole transport/injection layer 26, and the blue luminescent layer 49 is arranged adjacent to the electron transport/injection layer 30; however, the order, that is, the positions of the luminescent layers 47, 48, and 49 are not limited to the example shown in the drawing.

Because three color luminescent layers 47, 48, and 49 are laminated as described above, as the light emitting device 15 is energized, the luminescent layers 47, 48, and 49 of the light emitting device 15 may cooperate to generate white light. However, in each of the light emitting devices 15, because of interference or resonance, a portion of light having a specific wavelength is intensified and a portion of light having the other wavelength is attenuated. That is, in the light emitting device 15R, within white light that is generated in the luminescent layers 47, 48, and 49 (particularly, light generated in the red luminescent layer 47), red color is intensified and then emitted from the transflective electrode 32. In the light emitting device 15G, within white light that is generated in the luminescent layers 47, 48, and 49 (particularly, light generated in the green luminescent layer 48), green color is intensified and then emitted from the transflective electrode 32. In the light emitting device 15B, within white light that is generated in the luminescent layers 47, 48, and 49 (particularly, light generated in the blue luminescent layer 49), blue color is intensified and then emitted from the transflective electrode 32.

Inside each of the luminescent layers 47, 48, and 49, light is not generated with a uniform intensity, but light is generated most intensively at a certain plane (a plane perpendicular to the sheet of FIG. 7 and is parallel to the boundary between the luminescent layer 47 and the hole transport/injection layer 26 in the drawing) and light is generated weakly at the other positions. In FIG. 7, a hypothetical line 47RS indicates a plane at which light is most intensively generated inside the red luminescent layer 47R of the light emitting device 15R, a hypothetical line 48GS indicates a plane at which light is most intensively generated inside the green luminescent layer 48G of the light emitting device 15G, and a hypothetical line 49BS indicates a plane at which light is most intensively generated inside the blue luminescent layer 49B of the light emitting device 15B.

In order to emit light from the transflective electrode 32R so that only red color is intensified in the light emitting device 15R, theoretically, In equation (66) and In equation (67) are preferably satisfied, and, furthermore, Equation (68) and Equation (69) are preferably satisfied, In equation (66) and In equation (67) are derived from Equation (68) and Equation (69), which are theoretical equalities, with a tolerance of ±20%. The reason why the tolerance is given is that complex multiple reflection may actually occur.

0.8×(2π·N_{R}+θ_{1R}+θ_{2R})×λ_{R}/(4π)≦L′_{R}≦1.2×(2π·N_{R}+θ_{1R}+θ_{2R})×λ_{R}/(4π) (66)

0.8×(2π·N_{0R}+θ_{1R})×λ_{R}/(4π)≦L′_{0R}≦1.2×(2π·N_{0R}+θ_{1R})×λ_{R}/(4π) (67)

(2π·N_{R}+θ_{1R}+θ_{2R})×λ_{R}/(4π)=L′_{R} (68)

(2π·N_{0R}+θ_{1R})×λ_{R}/(4π)=L′_{0R} (69)

Here, λ_{R} denotes the peak wavelength of red light (λ_{R} may be, for example, set to 620 nm) that is emitted through the transflective electrode 32R, θ_{1R} denotes the phase shift (rad) of light having a wavelength λ_{R} when the light is reflected on the reflective layer 22R, θ_{2R} denotes the phase shift (rad) of light having a wavelength λ_{R} when the light is reflected on the transflective electrode 32R, N_{R} denotes an integer that is equal to or larger than 1, and NOR denotes an integer that is equal to or larger than 1.

L′_{R} in In equation (66) and Equation (68) denotes an optical length in the light emitting device 15R between the reflective layer 22R and the transflective electrode 32R, and is expressed by Equation (70).

$${L}_{R}^{′} = {\sum }_{iR = 1}^{X} {n}_{iR} {d}_{iR} \qquad ( 70 )$$

In Equation (70), n_{iR} denotes the refractive index of a layer in the light emitting device 15R, and d_{iR} denotes the thickness of a layer in the light emitting device 15R. In Equation (70), iR ranges from 1 to X and denotes a layer between the reflective layer 22R and the transflective electrode 32R. X is the total number of these layers.

Specifically, in the embodiment shown in the drawing, the optical length L′_{R} in the light emitting device 15R between the reflective layer 22R and the transflective electrode 32R is expressed by Equation (71).

L′_{R}=n_{1R}·d_{1R}+n_{2R}·d_{2R}+n_{3R}·d_{3R}+n_{4R}·d_{4R}+n_{5R}·d_{5R}+n_{6R}·d_{6R} (71)

Here, n_{1R} denotes the refractive index of the transparent electrode 24R, and d_{1R} denotes the thickness of the transparent electrode 24R. n_{2R} denotes the refractive index of the hole transport/injection layer 26R, and d_{2R} denotes the thickness of the hole transport/injection layer 26R. n_{3R} denotes the refractive index of the red luminescent layer 47R, and d_{3R} denotes the thickness of the red luminescent layer 47R. n_{4R} denotes the refractive index of the green luminescent layer 48R, and d_{4R} denotes the thickness of the green luminescent layer 48R. n_{5R} denotes the refractive index of the blue luminescent layer 49R, and d_{5R} denotes the thickness of the blue luminescent layer 49R. n_{6R} denotes the refractive index of the electron transport/injection layer 30R, and d_{6R} denotes the thickness of the electron transport/injection layer 30R.

L′_{0R} in In equation (67) and Equation (69) denotes the optical length between the plane 47RS, at which light is most intensively generated in the red luminescent layer 47R, and the reflective layer 22R, and is expressed by Equation (72)

$${L}_{0 R}^{′} = {n}_{NR} {d}_{N 1 R} + {\sum }_{iR = 1}^{M} {n}_{iR} {d}_{iR} \qquad ( 72 )$$

In Equation (72), n_{iR} denotes the refractive index of a layer in the light emitting device 15R, and d_{iR} denotes the thickness of a layer in the light emitting device 15R. In Equation (72), iR ranges from 1 to M and denotes a layer between the reflective layer 22R and the red luminescent layer 47R. M is the total number of these layers. n_{NR} denotes the refractive index of the red luminescent layer 47R, d_{N1R} denotes a distance between the plane 47RS, at which light is most intensively generated in the red luminescent layer 47R, and the hole transport/injection layer 26R.

Specifically, in the embodiment shown in the drawing, the optical length L′_{0R} between the plane 47RS, at which light is most intensively generated in the red luminescent layer 47R, and the reflective layer 22R is expressed by Equation (73).

L′_{0R}=n_{3R}·d_{31R}+n_{1R}·d_{1R}+n_{2R}·d_{2R} (73)

Here, d_{31R} denotes a distance between the plane 47RS, at which light is most intensively generated in the red luminescent layer 47R, and the hole transport/injection layer 26R.

In order to emit light from the transflective electrode 32 in such a manner that only green color is intensified in the light emitting device 15G, theoretically, In equation (74) and In equation (75) are preferably satisfied, and, furthermore, Equation (76) and Equation (77) are preferably satisfied. In equation (74) and In equation (75) are derived from Equation (76) and Equation (77), which are theoretical equalities, with a tolerance of ±20%. The reason why the tolerance is given is that complex multiple reflection may actually occur.

0.8×(2π·N_{G}+θ_{1G}+θ_{2G})×λ_{G}/(4π)≦L′_{G}≦1.2×(2π·N_{G}+θ_{1G}+θ_{2G})×λ_{G}/(4π) (74)

0.8×(2π·N_{0G}+θ_{1G})×λ_{G}/(4π)≦L′_{0G}≦1.2×(2π·N_{0G}+θ_{1G})×λ_{G}/(4π) (75)

(2π·N_{G}+θ_{1G}+θ_{2G})×λ_{G}/(4π)=L′_{G} (76)

(2π·N_{0G}+θ_{1G})×λ_{G}/(4π)=L′_{0G} (77)

Here, λ_{G} denotes the peak wavelength of green light (λ_{G} may be, for example, set to 540 nm) that is emitted through the transflective electrode 32G, θ_{1G} denotes the phase shift (rad) of light having a wavelength λ_{G} when the light is reflected on the reflective layer 22G, θ_{2G} denotes the phase shift (rad) of light having a wavelength λ_{G} when the light is reflected on the transflective electrode 32G, N_{G} denotes an integer that is equal to or larger than 1, and N_{0G} denotes an integer that is equal to or larger than 1.

L′_{G} in In equation (74) and Equation (76) denotes an optical length in the light emitting device 15G between the reflective layer 22G and the transflective electrode 32G, and is expressed by Equation (78).

$${L}_{G}^{′} = {\sum }_{iG = 1}^{X} {n}_{iG} {d}_{iG} \qquad ( 78 )$$

In Equation (78), n_{iG} denotes the refractive index of a layer in the light emitting device 15G, and d_{iG} denotes the thickness of a layer in the light emitting device 15G. In Equation (78), iG ranges from 1 to X and denotes a layer between the reflective layer 22G and the transflective electrode 32G. X is the total number of these layers.

Specifically, in the embodiment shown in the drawing, the optical length L′_{G} in the light emitting device 15G between the reflective layer 22G and the transflective electrode 32G is expressed by Equation (79).

L′_{G}=n_{1G}·d_{1G}+n_{2G}·d_{2G}+n_{3G}·d_{3G}+n_{4G}·d_{4G}+n_{5G}·d_{5G}+n_{6G}·d_{6G} (79)

Here, n_{1G} denotes the refractive index of the transparent electrode 24G, and d_{1G} denotes the thickness of the transparent electrode 24G. n_{2G} denotes the refractive index of the hole transport/injection layer 26G, and d_{2G} denotes the thickness of the hole transport/injection layer 26G. n_{3G} denotes the refractive index of the red luminescent layer 47G, and d_{3G} denotes the thickness of the red luminescent layer 47G. n_{4G} denotes the refractive index of the green luminescent layer 48G, and d_{4G} denotes the thickness of the green luminescent layer 48G. n_{5G} denotes the refractive index of the blue luminescent layer 49G, and d_{5G} denotes the thickness of the blue luminescent layer 49G. n_{6G} denotes the refractive index of the electron transport/injection layer 30G, and d_{6G} denotes the thickness of the electron transport/injection layer 30G.

L′_{0G} in In equation (75) and Equation (77) denotes the optical length between the plane 48GS, at which light is most intensively generated in the green luminescent layer 48G, and the reflective layer 22G, and is expressed by Equation (80).

$${L}_{0 G}^{′} = {n}_{NG} {d}_{N 1 G} + {\sum }_{iG = 1}^{M} {n}_{iG} {d}_{iG} \qquad ( 80 )$$

In Equation (80), n_{iG} denotes the refractive index of a layer in the light emitting device 15G, and d_{iG} denotes the thickness of a layer in the light emitting device 15G. In Equation (80), iG ranges from 1 to M and denotes a layer between the reflective layer 22G and the green luminescent layer 48G. M is the total number of these layers, n_{NG} denotes the refractive index of the green luminescent layer 48G, d_{N1G} denotes a distance between the plane 48GS, at which light is most intensively generated in the green luminescent layer 48G, and the red luminescent layer 47G.

Specifically, in the embodiment shown in the drawing, the optical length L′_{0G} between the plane 48GS, at which light is most intensively generated in the green luminescent layer 48G, and the reflective layer 22G is expressed by Equation (81),

L′_{0G}=n_{4G}·d_{41G}+n_{1G}·d_{1G}+n_{2G}·d_{2G}+n_{3G}·d_{3G} (81)

Here, d_{41G} denotes a distance between the plane 48GS, at which light is most intensively generated in the green luminescent layer 48G, and the red luminescent layer 47G.

In order to emit light from the transflective electrode 32 in such a manner that only blue color is intensified in the light emitting device 15B, theoretically, In equation (82) and In equation (83) are preferably satisfied, and, furthermore, Equation (84) and Equation (85) are preferably satisfied. In equation (82) and In equation (83) are derived from Equation (84) and Equation (85), which are theoretical equalities, with a tolerance of ±20%. The reason why the tolerance is given is that complex multiple reflection may actually occur.

0.8×(2π·N_{B}+θ_{1B}+θ_{2B})×λ_{B}/(4π)≦L′_{B}≦1.2×(2π·N_{B}+θ_{1B}+θ_{2B})×λ_{B}/(4π) (82)

0.8×(2π·N_{0B}+θ_{1B})×λ_{B}/(4π)≦L′_{0B}≦1.2×(2π·N_{0B}+θ_{1B})×λ_{B}/(4π) (83)

(2π·N_{B}+θ_{1B}+θ_{2B})×λ_{B}/(4π)=L′_{B} (84)

(2π·N_{0B}+θ_{1B})×λ_{B}/(4π)=L′_{0B} (85)

Here, λ_{B} denotes the peak wavelength of blue light (λ_{B} may be, for example, set to 470 nm) that is emitted through the transflective electrode 32B, θ_{1B} denotes the phase shift (rad) of light having a wavelength λ_{B} when the light is reflected on the reflective layer 22B, θ_{2B} denotes the phase shift (rad) of light having a wavelength λ_{B} when the light is reflected on the transflective electrode 32B, N_{B} denotes an integer that is equal to or larger than 1, and N_{0B} denotes an integer that is equal to or larger than 1.

L′_{B} in In equation (82) and Equation (84) denotes an optical length in the light emitting device 15B between the reflective layer 22B and the transflective electrode 32B, and is expressed by Equation (86).

$${L}_{B}^{′} = {\sum }_{iB = 1}^{X} {n}_{iB} {d}_{iB} \qquad ( 86 )$$

In Equation (86), n_{iB} denotes the refractive index of a layer in the light emitting device 15B, and d_{iB} denotes the thickness of a layer in the light emitting device 15B. In Equation (86), iB ranges from 1 to X and denotes a layer between the reflective layer 22B and the transflective electrode 32B. X is the total number of these layers.

Specifically, in the embodiment shown in the drawing, the optical length L′_{B} in the light emitting device 15B between the reflective layer 22B and the transflective electrode 32B is expressed by Equation (87).

L′_{B}=n_{1B}·d_{1B}+n_{2B}·d_{2B}+n_{3B}·d_{3B}+n_{4B}·d_{4B}+n_{5B}·d_{5B}+n_{6B}·d_{6B} (87)

Here, n_{1B} denotes the refractive index of the transparent electrode 24B, and d_{1B} denotes the thickness of the transparent electrode 24B. n_{2B} denotes the refractive index of the hole transport/injection layer 26B, and d_{2B} denotes the thickness of the hole transport/injection layer 26B. n_{3B} denotes the refractive index of the red luminescent layer 47B, and d_{3B} denotes the thickness of the red luminescent layer 47B. n_{4B} denotes the refractive index of the green luminescent layer 48B and d_{4B} denotes the thickness of the green luminescent layer 48B. n_{5B} denotes the refractive index of the blue luminescent layer 49B, and d_{5B} denotes the thickness of the blue luminescent layer 49B. n_{6B} denotes the refractive index of the electron transport/injection layer 30B, and d_{6B} denotes the thickness of the electron transport/injection layer 30B.

L′_{0B} in In equation (83) and Equation (85) denotes the optical length between the plane 49BS, at which light is most intensively generated in the blue luminescent layer 49B, and the reflective layer 22B, and is expressed by Equation (88).

$${L}_{0 B}^{′} = {n}_{NB} {d}_{N 1 B} + {\sum }_{iB = 1}^{M} {n}_{iB} {d}_{iB} \qquad ( 88 )$$

In Equation (88), n_{iB} denotes the refractive index of a layer in the light emitting device 15B, and d_{iB} denotes the thickness of a layer in the light emitting device 15B. In Equation (88), iB ranges from 1 to M and denotes a layer between the reflective layer 22B and the blue luminescent layer 49B. M is the total number of these layers. n_{NB} denotes the refractive index of the blue luminescent layer 49B, d_{N1B} denotes a distance between the plane 49BS, at which light is most intensively generated in the blue luminescent layer 49B, and the green luminescent layer 48B.

Specifically, in the embodiment shown in the drawing, the optical length L′_{0B} between the plane 49BS, at which light is most intensively generated in the blue luminescent layer 49B, and the reflective layer 22B is expressed by Equation (89).

L′_{0B}=n_{5B}·d_{51B}+n_{1B}·d_{1B}+n_{2B}·d_{2B}+n_{3B}·d_{3B}+n_{4B}·d_{4B} (89)

Here, d_{51B} denotes a distance between the plane 49BS, at which light is most intensively generated in the blue luminescent layer 49B, and the green luminescent layer 48B.

### Alternative Embodiments

In the organic EL devices 1, 10, and 11 according to the above described embodiments, each of the luminescent layers is formed of a low molecular material, and the layers from the anode to the cathode are, for example, formed in a vacuum by means of a deposition method, such as vapor deposition. However, each of the luminescent layers may be formed of a macromolecular material, and at least one of layers from the anode to the cathode may be formed by means of a liquid supplying method, such as an ink jet method and a dispenser method.

In addition, the layers from the anode to the cathode are not limited to the layers shown in the drawings, but another layer may also be provided.

In the organic EL devices 1, 10, and 11 according to the above described embodiments, the reflective layer 22 is in contact with the transparent electrode 24. However, for example, a layer formed of an insulative transparent material, such as silicon oxide, may be arranged between the reflective layer 22 and the transparent electrode 24.

In the organic EL devices 1, 10, and 11 according to the above described embodiments, the electrode and the transflective layer are implemented as one transflective electrode 32. However, the electrode 32 may be formed of a high translucent material, and a transflective layer formed of a material that is different from the material of the electrode 32 may be arranged on the opposite side with respect to the luminescent layer 28 with the electrode 32 arranged between the transflective layer and the luminescent layer 28. Furthermore, a layer formed of a high translucent material may be arranged between the electrode and the transflective layer.

The organic EL devices 1, 10, and 11 according to the above described embodiments are of top emission type. However, the aspects of the invention may be applied to a bottom emission type. In the case of the bottom emission type, it is only necessary that the reflective layer is arranged at a position farther from the substrate than the transflective layer is, and the luminescent layer is arranged between the reflective layer and the transflective layer.

In the above described embodiments, the optical lengths L′_{0R}, L′_{0G}, and L′_{0B} are set in such a manner that all the thicknesses d_{1R}, d_{1G}, and d_{1B} of ITO are made equal, and the thicknesses d_{2R}, d_{2G}, and d_{2B} of the hole transport/injection layers are respectively adjusted. However, the optical lengths L′_{0R}, L′_{0G}, and L′_{0B} may also be set in such a manner that all the thicknesses d_{2R}, d_{2G}, and d_{2B} of the hole transport/injection layers are made equal, and the thicknesses d_{1R}, d_{1G}, and d_{1B} of ITO are respectively adjusted. In this manner, it is possible to form a plurality of pixels (light emitting devices) of the hole transport/injection layers at the same time and, therefore, it is advantageous in manufacturing.

### Applications

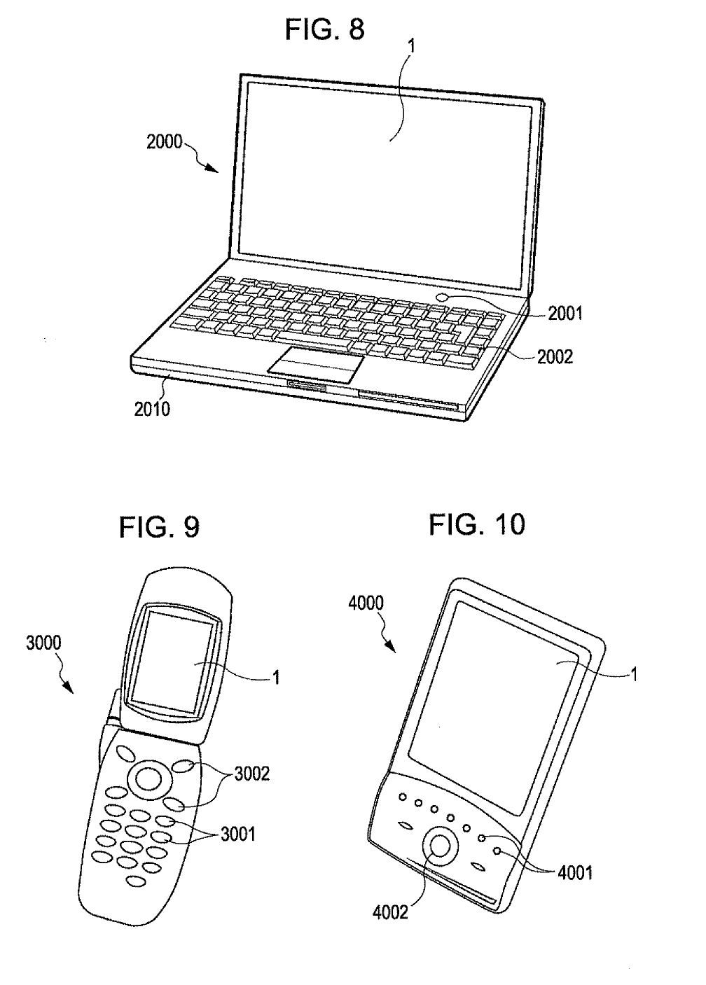

Next, an electronic apparatus that employs the organic EL device according to the aspects of the invention will be described. FIG. 8 is a perspective view that shows the configuration of a mobile personal computer that uses the organic EL device 1, 10 or 11 according to the above embodiments as an image display device. The personal computer 2000 includes the organic EL device 1, which serves as a display device, and a body portion 2010. The body portion 2010 is provided with a power switch 2001 and a keyboard 2002. FIG. 9 is a view of a cellular phone that employs the organic EL device 1, 10 or 11 according to the above embodiments. The cellular phone 3000 includes a plurality of operating buttons 3001, a plurality of scroll buttons 3002, and the organic EL device 1, which serves as a display device. By manipulating the scroll buttons 3002, an image displayed on the organic EL device 1 is scrolled. FIG. 10 is a view of a personal digital assistant (PDA) that employs the organic EL device 1, 10 or 11 according to the above embodiments. The personal digital assistant 4000 includes a plurality of operating buttons 4001, a power switch 4002, and the organic EL device 1, which serves as a display device. As the power switch 4002 is manipulated, various pieces of information, such as an address book and a schedule book, are displayed on the organic EL device 1.

The electronic apparatuses that employ the organic EL device according to the aspects of the invention include, in addition to the apparatuses shown in FIG. 8 to FIG. 10, a digital still camera, a television, a video camera, a car navigation system, a pager, an electronic personal organizer, an electronic paper, an electronic calculator, a word processor, a workstation, a video telephone, a POS terminal, a video player, and devices provided with a touch panel.

What is claimed is:

1. An organic electroluminescent device comprising:
substrate;
a transflective layer;
a translucent first electrode between the substrate and the transflective layer;
a luminescent layer between the first electrode and the transflective layer; and
a reflective layer that between the substrate and the luminescent layer, the reflective layer reflecting light from the luminescent layer toward the second electrode; and
an optical length L′ between the reflective layer and the transflective layer falls within a range that satisfies the following relationship:
0.8×(2π·N+θ1+θ2)×λ/(4π)≦L′≦1.2×(2π·N+θ1+θ2)×λ/(4π), and
an optical length L′0 between the reflective layer and a position at which light is most intensively generated in the luminescent layer falls within a range that satisfies the following relationship:
0.8×(2π·N0+θ1)×λ/(4π)≦L′0≦1.2×(2π·N0+θ1)×λ/(4π)
where:
λ denotes a peak wavelength of light that is emitted through the second electrode,
θ1 denotes a phase shift (rad) of light having a wavelength
λ when the light is reflected on the reflective layer,
θ2 is a phase shift (rad) of light having a wavelength λ when the light is reflected on the transflective layer,
N is an integer that is equal to or larger than 1, and
N0 is an integer that is equal to or larger than 1.

2. The organic electroluminescent according to claim 1, wherein the transflective layer serves as a second electrode opposite from the first electrode with the luminescent layer disposed therebetween.

3. The organic electroluminescent according to claim 1, further comprising a second electrode between the transflective layer and the luminescent layer.

4. An organic electroluminescent device comprising:
a light emitting device of which the color of emitted light is red;
a light emitting device of which the color of emitted light is green; and
a light emitting device of which the color of emitted light is blue, wherein
each of the light emitting devices includes:
a transflective layer;
a translucent first electrode between the substrate and the transflective layer;
a luminescent layer between the first electrode and the transflective layer; and
a reflective layer that between the substrate and the luminescent layer, the reflective layer reflecting light from the luminescent layer toward the second electrode; and
an optical length L′ between the reflective layer and the transflective layer falls within a range that satisfies the following relationship:
0.8×(2π·N+θ1+θ2)×λ/(4π)≦L′≦1.2×(2π·N+θ1+θ2)×λ/(4π), and
an optical length L′0 between the reflective layer and a position at which light is most intensively generated in the luminescent layer falls within a range that satisfies the following relationship:
0.8×(2π·N0+θ1)×λ/(4π)≦L′0≦1.2×(2π·N0+θ1)×λ/(4π)
where:
λ denotes a peak wavelength of light that is emitted through the second electrode,
θ1 denotes a phase shift (rad) of light having a wavelength
λ when the light is reflected on the reflective layer,
θ2 is a phase shift (rad) of light having a wavelength λ when the light is reflected on the transflective layer,
N is an integer that is equal to or larger than 1, and
N0 is an integer that is equal to or larger than 1.

5. The organic electroluminescent according to claim 4, wherein the transflective layer serves as a second electrode opposite from the first electrode with the luminescent layer disposed therebetween.

6. The organic electroluminescent according to claim 4, further comprising a second electrode between the transflective layer and the luminescent layer.

7. An organic electroluminescent device comprising:
a light emitting device of which the color of emitted light is red;
a light emitting device of which the color of emitted light is green; and
a light emitting device of which the color of emitted light is blue, wherein
each of the light emitting devices includes:
substrate;
a transflective layer;
a translucent first electrode between the substrate and the transflective layer;
a luminescent layer between the first electrode and the transflective layer; and
a reflective layer that between the substrate and the luminescent layer, the reflective layer reflecting light from the luminescent layer toward the second electrode; and
in each of the light emitting devices, the luminescent layer includes a first luminescent layer of which generated light has a peak intensity at a wavelength corresponding to yellow color, orange color, or red color, and a second luminescent layer of which generated light has a peak intensity at a wavelength corresponding to cyan color or blue color, wherein the first luminescent layer and the second luminescent layer are laminated,
in regard to the light emitting device of which the color of emitted light is red, an optical length L′_{R} between the reflective layer and the transflective layer falls within a range that is expressed by 0.8×(2π·N_{R}+θ_{1R}+θ_{2R})×λ_{R}/(4π)≦L′_{R}≦1.2×(2π·N_{R}+θ_{1R}+θ_{2R})×λ_{R}/(4π),
in regard to the light emitting device of which the color of emitted light is red, an optical length L′_{0R} between a position, at which light is most intensively generated in the first luminescent layer, and the reflective layer falls within a range that is expressed by 0.8×(2π·N_{0R}+θ_{1R})×λ_{R}/(4π)≦L′_{0R}≦1.2×(2π·N_{0R}+θ_{1R})×λ_{R}/(4π), wherein
where:
λ_{R} denotes a peak wavelength of red light that is emitted through the second electrode,
θ_{1R} denotes a phase shift (rad) of light having a wavelength
λ_{R} when the light is reflected on the reflective layer,
θ_{2R} denotes the phase shift (rad) of light having a wavelength λ_{R} when the light is reflected on the transflective layer,
N_{R} denotes an integer that is equal to or larger than 1, and
N_{0R} denotes an integer that is equal to or larger than 1, and
in regard to the light emitting device of which the color of emitted light is red, an optical length L′_{0R} between a position, at which light is most intensively generated in the first luminescent layer, and the reflective layer falls within a range that is expressed by 0.8×(2π·N_{0R}+θ_{1R})×λ_{R}/(4π)≦L′_{0R}≦1.2×(2π·N_{0R}+θ_{1R})×λ_{R}/(4π),
in regard to the light emitting device of which the color of emitted light is green, an optical length L′_{0G} between a position, at which light is most intensively generated in the first or second luminescent layer, and the reflective layer falls within a range that is expressed by 0.8×(2π·N_{0G}+θ_{1G})×λ_{G}/(4π)≦L′_{0G}≦1.2×(2π·N_{0G}+θ_{1G})×λ_{G}/(4π), wherein
where:
λ_{G} denotes a peak wavelength of green light that is emitted through the second electrode,
θ_{1G} denotes a phase shift (rad) of light having a wavelength
λ_{G} when the light is reflected on the reflective layer,
θ_{2G} denotes the phase shift (rad) of light having a wavelength λ_{G} when the light is reflected on the transflective layer,
N_{G} denotes an integer that is equal to or larger than 1, and
N_{0G} denotes an integer that is equal to or larger than 1,
in regard to the light emitting device of which the color of emitted light is blue, an optical length L′_{B} between the reflective layer and the transflective layer falls within a range that is expressed by 0.8×(2π·N_{B}+θ_{1B}+θ_{2B})×λ_{B}/(4π)≦L′_{B}≦1.2×(2π·N_{B}+θ_{1B}+θ_{2B})×λ_{B}/(4π), and
in regard to the light emitting device of which the color of emitted light is blue, an optical length L′_{0B} between a position, at which light is most intensively generated in the second luminescent layer, and the reflective layer falls within a range that is expressed by 0.8×(2π·N_{0B}+θ_{1B})×λ_{B}/(4π)≦L′_{0B}≦1.2×(2π·N_{0B}+θ_{1B})×λ_{B}/(4π), wherein
where:
λ_{B} denotes a peak wavelength of blue light that is emitted through the second electrode,
θ_{1B} denotes a phase shift (rad) of light having a wavelength
λ_{B} when the light is reflected on the reflective layer,
θ_{2B} denotes the phase shift (rad) of light having a wavelength λ_{B} when the light is reflected on the transflective layer,
N_{B} denotes an integer that is equal to or larger than 1, and
N_{0B} denotes an integer that is equal to or larger than 1.

8. The organic electroluminescent according to claim 7, wherein the transflective layer serves as a second electrode opposite from the first electrode with the luminescent layer disposed therebetween.

9. The organic electroluminescent according to claim 7, further comprising a second electrode between the transflective layer and the luminescent layer.

10. An organic electroluminescent device comprising:
a light emitting device of which the color of emitted light is red;
a light emitting device of which the color of emitted light is green; and
a light emitting device of which the color of emitted light is blue, wherein
each of the light emitting devices includes:
substrate;
a transflective layer;
a translucent first electrode between the substrate and the transflective layer;
a luminescent layer between the first electrode and the transflective layer; and
a reflective layer that between the substrate and the luminescent layer, the reflective layer reflecting light from the luminescent layer toward the second electrode; and
in each of the light emitting devices, the luminescent layer includes a red luminescent layer of which generated light has a peak intensity at a wavelength corresponding to red color, a green luminescent layer of which generated light has a peak intensity at a wavelength corresponding to green color, and a blue luminescent layer of which generated light has a peak intensity at a wavelength corresponding to blue color, wherein the red luminescent layer, the green luminescent layer, and the blue luminescent layer are laminated,
in regard to the light emitting device of which the color of emitted light is red, an optical length L′_{R} between the reflective layer and the transflective layer falls within a range that is expressed by 0.8×(2π·N_{R}+θ_{1R}+θ_{2R})×λ_{R}/(4π)≦L′_{R}≦1.2×(2π·N_{R}+θ_{1R}+θ_{2R})×λ_{R}/(4π), and
in regard to the light emitting device of which the color of emitted light is red, an optical length L′_{0R} between a position, at which light is most intensively generated in the red luminescent layer, and the reflective layer falls within a range that is expressed by 0.8×(2π·N_{0R}+θ_{1R})×λ_{R}/(4π)≦L′_{0R}≦1.2×(2π·N_{0R}+θ_{1R})×λ_{R}/(4π), wherein
where:
λ_{R} denotes a peak wavelength of red light that is emitted through the second electrode,
θ_{1R} denotes a phase shift (rad) of light having a wavelength
λ_{R} when the light is reflected on the reflective layer,
θ_{2R} denotes the phase shift (rad) of light having a wavelength λ_{R} when the light is reflected on the transflective layer,
N_{R} denotes an integer that is equal to or larger than 1, and
N_{0R} denotes an integer that is equal to or larger than 1,
in regard to the light emitting device of which the color of emitted light is green, an optical length L′_{G} between the reflective layer and the transflective layer falls within a range that is expressed by 0.8×(2π·N_{G}+θ_{1G}+θ_{2G})×λ_{G}/(4π)≦L′_{G}≦1.2×(2π·N_{G}+θ_{1G}+θ_{2G})×λ_{G}/(4π), and
in regard to the light emitting device of which the color of emitted light is green, an optical length L′_{0G} between a position, at which light is most intensively generated in the green luminescent layer, and the reflective layer falls within a range that is expressed by 0.8×(2π·N_{0G}+θ_{1G})×λ_{G}/(4π)≦L′_{0G}≦1.2×(2π·N_{0G}+θ_{1G})×λ_{G}/(4π), wherein
where:
λ_{G} denotes a peak wavelength of green light that is emitted through the second electrode,
θ_{1G} denotes a phase shift (rad) of light having a wavelength
λ_{G} when the light is reflected on the reflective layer,
θ_{2G} denotes the phase shift (rad) of light having a wavelength λ_{G} when the light is reflected on the transflective layer,
N_{G} denotes an integer that is equal to or larger than 1, and
N_{0G} denotes an integer that is equal to or larger than 1,
in regard to the light emitting device of which the color of emitted light is blue, an optical length L′_{B} between the reflective layer and the transflective layer falls within a range that is expressed by 0.8×(2π·N_{B}+θ_{1B}+θ_{2B})×λ_{B}/(4π)≦L′_{B}≦1.2×(2π·N_{B}+θ_{1B}+θ_{2B})×λ_{B}/(4π), and
in regard to the light emitting device of which the color of emitted light is blue, an optical length L′_{0B} between a position, at which light is most intensively generated in the blue luminescent layer, and the reflective layer falls within a range that is expressed by 0.8×(2π·N_{0B}+θ_{1B})×λ_{B}/(4π)≦L′_{0B}≦1.2×(2π·N_{0B}+θ_{1B})×λ_{B}/(4π) wherein
where:
λ_{B} denotes a peak wavelength of blue light that is emitted through the second electrode,
θ_{1B} denotes a phase shift (rad) of light having a wavelength
λ_{B} when the light is reflected on the reflective layer,
θ_{2B} denotes the phase shift (rad) of light having a wavelength λ_{B} when the light is reflected on the transflective layer,
N_{B} denotes an integer that is equal to or larger than 1, and
N_{0B} denotes an integer that is equal to or larger than 1.

11. The organic electroluminescent according to claim 10, wherein the transflective layer serves as a second electrode opposite from the first electrode with the luminescent layer disposed therebetween.

12. The organic electroluminescent according to claim 10, further comprising a second electrode between the transflective layer and the luminescent layer.

13. An electronic apparatus comprising the organic electroluminescent device according to claim 1.

14. An electronic apparatus comprising the organic electroluminescent device according to claim 4.

15. An electronic apparatus comprising the organic electroluminescent device according to claim 7.

16. An electronic apparatus comprising the organic electroluminescent device according to claim 10.
